(19) United States
(12) Patent Application Publication
(10) Pub. No.: US 2025/0386682 A1
(43) Pub. Date: Dec. 18, 2025

(54) ELECTRONIC DEVICE

(71) Applicant: InnoLux Corporation, Miao-Li County (TW)

(72) Inventors: Hsiao-Lang LIN, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 19/212,659

(22) Filed: May 19, 2025

(30) Foreign Application Priority Data
Jun. 18, 2024 (CN) 202410783392.7

(51) Int. Cl. H10K 59/124; H10K 39/34; H10K 59/121

(52) U.S. Cl. CPC H10K 59/124; H10K 39/34; H10K 59/1213

(57) ABSTRACT

An electronic device includes a substrate, a plurality of transistors disposed on the substrate, a light emitting unit disposed on at least one of the plurality of transistors, a first insulating layer disposed on the light emitting unit and an optical unit. The first insulating layer has a first opening and a second opening, and the optical unit is disposed in the first opening. In a top view of the electronic device, the first opening is overlapped with at least a portion of the light emitting unit, and the second opening is overlapped with at least a portion of at least one of the plurality of transistors.

### BACKGROUND OF THE DISCLOSURE

### 1. Field of the Disclosure

The present disclosure relates to an electronic device, and more particularly to an electronic device including a hole structure.

### 2. Description of the Prior Art

As types or numbers of the layers on the circuit layer of the electronic device increase, the inspecting step and/or repair step of the electronic elements (such as transistors) in the circuit layer may be affected by the layers on the circuit layer, which may cause the problem that the electronic elements cannot be effectively repaired. In addition, some elements (such as alignment element) disposed in the electronic device may be shielded by the layers on the circuit layer and lose their function. Therefore, to solve the above-mentioned problems is still an important issue in the present field.

### SUMMARY OF THE DISCLOSURE

The present disclosure aims at providing an electronic device including hole structures, wherein the hole structures may be used to assist the perform of specific process or reduce the influence of the layers on the circuit layer on specific elements.

In some embodiments, an electronic device is provided by the present disclosure. The electronic device includes a substrate, a plurality of transistors disposed on the substrate, a light emitting unit disposed on at least one of the plurality of transistors, a first insulating layer disposed on the light emitting unit and an optical unit. The first insulating layer has a first opening and a second opening, and the optical unit is disposed in the first opening. In a top view of the electronic device, the first opening is overlapped with at least a portion of the light emitting unit, and the second opening is overlapped with at least a portion of at least one of the plurality of transistors.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a partial cross-sectional view of an electronic device according to a first embodiment of the present disclosure.

FIG. 2 schematically illustrates a partial top view of an electronic device according to a second embodiment of the present disclosure.

FIG. 3 schematically illustrates a cross-sectional view of a transistor of the electronic device according to the second embodiment of the present disclosure.

FIG. 4 schematically illustrates a partial top view of an electronic device according to a third embodiment of the present disclosure.

FIG. 5 schematically illustrates a partial top view of an electronic device according to a fourth embodiment of the present disclosure.

FIG. 6 schematically illustrates a partial top view of an electronic device according to a fifth embodiment of the present disclosure.

FIG. 7 schematically illustrates a partial top view of an electronic device according to a sixth embodiment of the present disclosure.

FIG. 8 schematically illustrates a partial top view of an electronic device according to a variant embodiment of the sixth embodiment of the present disclosure.

FIG. 9 schematically illustrates a partial cross-sectional view of an electronic device according to a seventh embodiment of the present disclosure.

FIG. 10 schematically illustrates a partial cross-sectional view of an electronic device according to an eighth embodiment of the present disclosure.

FIG. 11 schematically illustrates a partial cross-sectional view of an electronic device according to a ninth embodiment of the present disclosure.

FIG. 12 shows the flow chart of the manufacturing process of the electronic device according to the first embodiment of the present disclosure.

FIG. 13 schematically illustrates a partial cross-sectional view of an electronic device according to a tenth embodiment of the present disclosure.

FIG. 14 shows the flow chart of the manufacturing process of the electronic device according to the tenth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a light emitting device, a display device, a sensing device, a back-light device, an antenna device, a tiled device or other suitable electronic devices, but not limited thereto. The electronic device of the present disclosure may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED), a quantum dot light emitting diode (QLED or QDLED) or an inorganic light emitting diode. The inorganic light emitting diode may for example include a mini light emitting diode (mini LED), a micro light emitting diode (micro LED) or a quantum dot light emitting diode (QLED), but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto. The electronic device of the present disclosure may be combinations of the above-mentioned devices, such as the combination of display device and other devices, but not limited thereto.

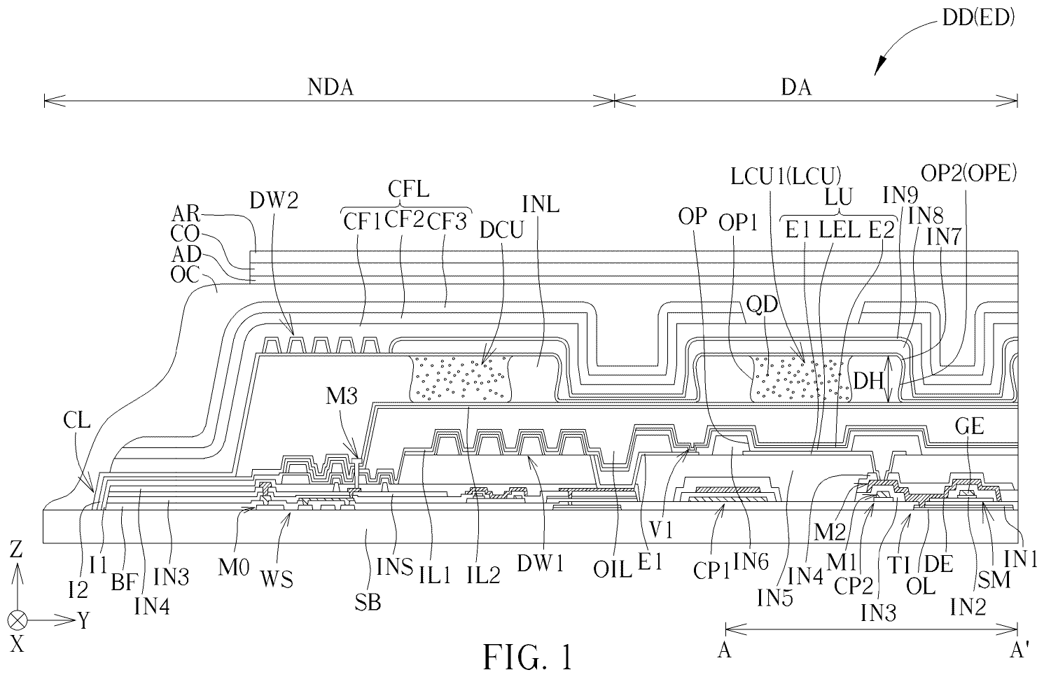

Referring to FIG. 1, FIG. 1 schematically illustrates a partial cross-sectional view of an electronic device according to a first embodiment of the present disclosure. The electronic device ED of the present disclosure may include a light emitting device for emitting a light. In an embodiment, the electronic device ED may include a display device DD for displaying pictures or images, but not limited thereto. In some embodiments, the electronic device ED may include combinations of the display device DD and other types of devices. As shown in FIG. 1, the electronic device ED may include a substrate SB, a circuit layer CL disposed on the substrate SB, electronic units (such as the light emitting units LU) disposed on the circuit layer CL and optical units LCU disposed on the light emitting units LU, but not limited thereto. It should be noted that the structure of the electronic device ED is not limited to what is shown in FIG. 1 and may include other elements and/or layers. The structures of the layers or the elements of the electronic device ED will be detailed in the following.

The substrate SB may be used for supporting the elements and the layers disposed thereon. The substrate SB may include a rigid material or a flexible material. The rigid material for example includes glass, quartz, sapphire, ceramic, other suitable materials or combinations of the above-mentioned materials. The flexible material for example includes polyimide (PI), polycarbonate (PC), polyethylene terephthalate (PET), other suitable materials or combinations of the above-mentioned materials. In some embodiments, the substrate SB may include a multi-layer structure, which is not limited to what is shown in FIG. 1.

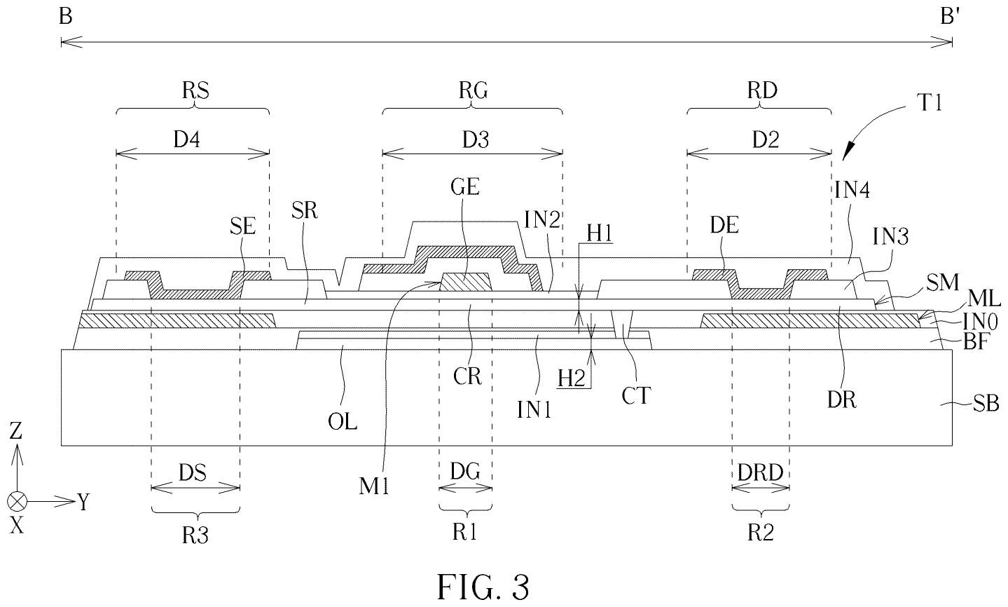

The circuit layer CL may include various kinds of wires, circuits or electronic units that can be applied to the electronic device ED. The electronic unit may include any suitable active elements and/or passive elements. The circuit layer CL may include any suitable structure formed by stacking conductive layer(s) and insulating layer(s), wherein the conductive layer (s) may be used for forming the wires, the circuits or the electronic units mentioned above. According to the present embodiment, the circuit layer CL may include a plurality of transistors, capacitors, nodes and/or signal feeder line, such as the transistor T1 shown in FIG. 1. It should be noted that FIG. 1 just exemplary shows the structure of a transistor T1, but not show the structure of other transistors, and the structure of other transistors may refer to the structure of the transistor T1, but not limited thereto. In other words, the electronic device ED may include a plurality of transistors disposed on the substrate SB. The plurality of transistors in the circuit layer CL may serve as the driving unit, the switch unit, the sensor driving unit or other suitable electronic units. For example, the transistor T1 shown in FIG. 1 may be electrically connected to the light emitting unit LU of the electronic device ED to drive the light emitting unit LU, that is, the transistor T1 may serve as the driving unit of the light emitting unit LU, but not limited thereto. The transistors (such as the transistor T1) in the circuit layer CL may include thin film transistors (TFT), but not limited thereto. Specifically, as shown in FIG. 1, the circuit layer CL may include a buffer layer BF, a semiconductor SM disposed on the buffer layer BF, a conductive layer M1 disposed on the semiconductor SM and a conductive layer M2 disposed on the conductive layer M1, wherein the conductive layer M1 may form a gate electrode GE of the transistor T1, and conductive layer M2 may form the source electrode and the drain electrode DE of transistor T1. In an embodiment, the circuit layer CL may further include a conductive layer M0 disposed between the buffer layer BF and the substrate SB. The gate electrode GE of the transistor T1 may correspond to the channel region of the semiconductor SM, and the source electrode and the drain electrode DE of the transistor T1 may be electrically connected to the source region and the drain region of the semiconductor SM respectively. It should be noted that FIG. 1 does not show the source electrode and the channel region, the source region and the drain region of the semiconductor SM, and these are labeled in FIG. 3. The conductive layer M1 and the conductive layer M2 may include any suitable conductive material, such as metal materials, but not limited thereto. The semiconductor SM may include any suitable semiconductor material. For example, the material of the semiconductor SM of the present embodiment may include metal oxides (such as indium gallium zinc oxide (IGZO)), amorphous-IGZO (a-IGZO), crystalline IGZO, crystal structure of spinel IGZO, crystalline thin film of c-axis aligned crystal IGZO (CAAC-IGZO), nano-crystalline IGZO (nc-IGZO, located between monocrystalline IGZO and amorphous-IGZO), primary crystalline IGZO thin film (the state that amorphous phase and nano-crystalline phase are mixed and coexist) or polycrystalline spinel IGZO, but not limited thereto. In other embodiments, the material of the semiconductor SM may include low temperature polysilicon (LTPS) or amorphous silicon (a-Si), but not limited thereto. In other embodiments, the material of the semiconductors SM in some transistors may include metal oxide materials, while the material of the semiconductors SM in some transistors may include low temperature polysilicon. Although the transistor T1 shown in FIG. 1 is a top gate thin film transistor, it is not limited in the present embodiment. In some embodiments, the transistor T1 may include a bottom gate thin film transistor, a dual gate (or double gate) thin film transistor, a multi-gate thin film transistor or other types of thin film transistors. The plurality of transistors in the electronic device ED may be the transistors of the same type of different types. As shown in FIG. 1, the electronic device ED may further include an insulating layer IN2 disposed between the gate electrode GE (or the conductive layer M1) and the semiconductor SM. The insulating layer IN2 may serve as the gate insulating layer of the transistor T1. It should be noted that although the insulating layer IN2 shown in FIG. 1 is a patterned layer, it is not limited in the present embodiment. In some embodiments, the insulating layer IN2 may be a continuous layer disposed on the semiconductor SM and the buffer layer BF. The electronic device ED may further include an insulating layer IN3 disposed between the conductive layer M1 and the conductive layer M2 and an insulating layer IN4 disposed on the conductive layer M2. The insulating layer IN2, the insulating layer IN3 and the insulating layer IN4 may include any suitable insulating material.

In some embodiments, the transistor T1 may further include a semiconductor OL disposed on the substrate SB. In other words, the transistor T1 may include two semiconductor layers (that is, the semiconductor SM and the semiconductor OL). The semiconductor OL may be disposed between the semiconductor SM and the substrate SB. For example, the semiconductor OL may be directly disposed on the buffer layer BF, but not limited thereto. In a top view (that is, the direction Z) of the electronic device ED, the semiconductor SM may at least partially overlap the semiconductor OL. In some embodiment, the electronic device ED may further include an insulating layer IN1, wherein the insulating layer IN1 is disposed between the semiconductor SM and the semiconductor OL. Specifically, the insulating layer IN1 may be directly disposed on the top surface of the semiconductor OL and directly contact the semiconductor OL. The semiconductor SM may be electrically connected to the semiconductor OL. In such condition, the source electrode (not shown in FIG. 1) and/or the drain electrode DE of the transistor T1 may be electrically connected to the semiconductor SM and the semiconductor OL. For example, the semiconductor SM may contact the semiconductor OL by making the conductive layer M2 or the conductive layer M1 (for example, the conductive layer M2 shown in FIG. 1) filled into the via penetrating the buffer layer BF and the insulating layer IN1, thereby being electrically connected to the semiconductor OL, but not limited thereto. In other embodiments, the semiconductor SM may be electrically connected to the semiconductor OL through other conductive layers. In some embodiments, the semiconductor SM may be transferred to the semiconductor OL through multiple conductive layers, thereby being electrically connected to the semiconductor OL. The insulating layer IN1 may include metal oxide materials, such as aluminum oxide, but not limited thereto. The insulating layer IN1 may serve as an etching stopping layer and/or a waterproof-and-oxygen blocking layer, thereby providing protection to the semiconductor OL. The material of the semiconductor OL may include indium zinc oxide (In—Zn—O), indium gallium zinc tin oxide (In—Ga—Zn—Sn—O), indium gallium tin oxide (In—Ga—Sn—O) or indium tin zinc oxide (In—Sn—Zn—O), but not limited thereto. The lattice structure of the semiconductor OL may be different from the lattice structure of the semiconductor SM. For example, the semiconductor OL may include poly-crystalling oxide materials, but not limited thereto. In the material of the semiconductor OL, the content percentage of the atom of indium may be greater than the content percentage of the atom of zinc, and the content percentage of the atom of zinc may be greater than the content percentage of the atom of gallium. The content percentage of the atom of indium and the content percentage of the atom of gallium in the material of the semiconductor SM may respectively be greater than the content percentage of the atom of indium and the content percentage of the atom of gallium in the material of the semiconductor OL. The content percentage of the atom of the oxides in the material of the semiconductor OL may be greater than the content percentage of the atom of the oxides in the material of the semiconductor SM. In the present embodiment, the carrier mobility of the semiconductor OL may be greater than the carrier mobility of the semiconductor SM. In such condition, by making the transistor T1 further include the semiconductor OL that is electrically connected to the semiconductor SM, the carrier mobility of the entire semiconductor of the transistor T1 may be improved. For example, after the semiconductor OL is disposed, the carrier mobility of the semiconductor (including the semiconductor SM and the semiconductor OL) of the transistor may be greater than 50 cm²/Vs, but not limited thereto. Therefore, the performance of the transistor T1 may be improved, thereby improving the performance of the electronic device ED. In the present embodiment, the semiconductor SM may have a thickness H1, and the semiconductor OL may have a thickness H2, wherein the thickness H2 may be less than the thickness H1. The thickness H1 and the thickness H2 are labeled in FIG. 3 and are not labeled in FIG. 1. The comparison of the thickness H1 of the semiconductor SM and the thickness H2 of the semiconductor OL may be performed at the portions of the semiconductor SM and the semiconductor OL that are overlapped with each other. Specifically, a portion of the semiconductor SM overlapped with the semiconductor OL may be confirmed, and the maximum thickness of the portion of the semiconductor SM may be defined as the thickness H1. Similarly, a portion of the semiconductor OL overlapped with the semiconductor SM may be confirmed, and the maximum thickness of the portion of the semiconductor OL may be defined as the thickness H2. In other embodiments, the thickness H1 and the thickness H2 may be defined through other suitable ways, which is not limited to the definition mentioned above. It should be noted that the above-mentioned feature that the transistor T1 includes the semiconductor OL is not limited to be applied to all transistors in the circuit layer CL. For example, in some embodiments, a portion of the transistor may include the semiconductor OL, while another portion of the transistor may not include the semiconductor OL.

In some embodiments, the circuit layer CL may further include capacitors, wherein the capacitors may be formed of different conductive layers and the insulating layer in the circuit layer CL. For example, as shown in FIG. 1, the circuit layer CL may include a capacitor CP1 and a capacitor CP2, wherein the capacitor CP1 and the capacitor CP2 may be formed of the conductive layer M1, the conductive layer M2, and the insulating layer IN3 sandwiched between the conductive layer M1 and the conductive layer M2, but not limited thereto. In other embodiments, the capacitor CP1 and the capacitor CP2 may be formed of other conductive layers. The capacitor CP1 and the capacitor CP2 may be used to stabilize the voltage of the electronic device ED when the electronic device ED is displaying images, thereby improving the display effect of the electronic device ED, but not limited thereto.

In some embodiments, the circuit layer CL may further include a wire structure WS, wherein the wire structure WS may be formed of the conductive layers in the circuit layer CL. In detail, the electronic device ED may include an active region DA and a peripheral region NDA. The active region DA may be the region in the electronic device ED where the main functions (such as displaying images, emitting light or being operated by a user) performed. In the present embodiment, the active region DA may be defined as the region of the minimum rectangle or the shape with minimum area enclosed by the outer edges (for example, the outer edge of the light emitting layer LEL of the light emitting unit LU) of the outermost light emitting units LU, but not limited thereto. In other embodiments, the shape, position or range of the active region DA may be defined through any suitable way. The peripheral region NDA may be defined as region in the electronic device ED except the active region DA, such as the non-display region or the non-light-emitting region. As shown in FIG. 1, the wire structure WS may be disposed in the peripheral region NDA. In the present embodiment, the wire structure WS may be formed of the conductive layer M0, the conductive layer M1, the conductive layer M2 and the conductive layer M3. Specifically, the electronic device ED may further include the conductive layer M0, wherein the conductive layer M0 may directly be disposed on the surface of the substrate SB, and the conductive layer M0 may extend on the surface of the substrate SB to be electrically connected to an external electronic element (not shown in FIG. 1). The conductive layer M1 may be electrically connected to the conductive layer M0 through the via penetrating the buffer layer BF. The electronic device ED may further include an insulating layer INS disposed between the insulating layer IN3 and the insulating layer IN4, and the conductive layer M2 may be electrically connected to the conductive layer M1 through the via penetrating the insulating layer INS and the insulating layer IN3. The electronic device ED may further include a conductive layer M3, wherein the conductive layer M3 may be disposed on the insulating layer 12 and may be electrically connected to the conductive layer M2. The conductive layers (such as the conductive layer M2 and the conductive layer M3) in the wire structure WS may extend in the active region DA and/or the peripheral region NDA of the electronic device ED and be electrically connected to any suitable electronic element (such as the transistor T1, but not limited thereto) in the electronic device ED. In some embodiments, the conductive layer M3 may be disposed at other suitable position of the electronic device ED. Therefore, the electronic elements in the electronic device ED may be electrically connected to external electronic elements through the wire structure WS. The materials of the conductive layer M0 and the conductive layer M3 may refer to the materials of the conductive layer M1 and the conductive layer M2 mentioned above. The insulating layer INS may include any suitable insulating material. It should be noted that the structure of the wire structure WS shown in FIG. 1 is exemplary, and it is not limited in the present disclosure. In other embodiments, the conductive layers in the wire structure WS may be connected in any way, such that the electronic elements in the electronic device ED may be electrically connected to the external electronic elements.

Although FIG. 1 just shows the transistor T1 disposed in the active region DA, the circuit layer CL may include the transistor(s) disposed in the peripheral region NDA. That is, the transistors in the circuit layer CL may be disposed in the active region DA and/or the peripheral region NDA of the electronic device ED. In addition, the structure of the circuit layer CL shown in FIG. 1 is exemplary, and it is not limited in the present disclosure. The circuit layer CL may further include other suitable elements or layers according to the design of the electronic device ED.

According to the present embodiment, as shown in FIG. 1, the electronic device ED may further include an insulating layer IN5, wherein the insulating layer IN5 may be disposed on the circuit layer CL and cover the elements in the circuit layer CL, such as the transistor T1, the capacitor CP1, the capacitor CP2, and the like, but not limited thereto. The top surface of the insulating layer IN5 (or the surface away from the circuit layer CL) may be a flat surface to facilitate the disposition of other elements and/or layers on the insulating layer IN5. In such condition, the insulating layer IN5 may serve as a planarization layer. The insulating layer IN5 may include any suitable insulating material.

The electronic unit may be disposed on the insulating layer IN5. In an embodiment, the electronic unit may include the light emitting unit LU as the light source of the electronic device ED. The light emitting unit LU may include a light emitting diode, but not limited thereto. In the present embodiment, the electronic device ED may include an organic light emitting diode display device, and the light emitting unit LU may include an organic light emitting diode, but not limited thereto. For example, as shown in FIG. 1, the light emitting unit LU may include an electrode E1, an electrode E2 and a light emitting layer LEL disposed between the electrode E1 and the electrode E2. The electrode E1 may be disposed on the insulating layer IN5, the light emitting layer LEL may be disposed on the electrode E1, and the electrode E2 may be disposed on the light emitting layer LEL. One of the electrode E1 and the electrode E2 may be anode, and another one of the electrode E1 and the electrode E2 may be cathode. For example, the electrode E1 may be an anode, and the electrode E2 may be a cathode, but not limited thereto. The electrode E1 may include any suitable conductive material, such as metal materials or transparent conductive materials, but not limited thereto. The electrode E2 may include any suitable conductive material, such as transparent conductive materials, but not limited thereto. The electronic device ED may further include an insulating layer IN6 disposed on the insulating layer IN5, wherein the insulating layer IN6 may include an opening OP and partially cover the electrode E1, and a portion of the electrode E1 may be exposed. A portion of the light emitting layer LEL may be disposed in the opening OP of the insulating layer IN6. Specifically, a light emitting unit LU may be formed of a portion of the electrode E1 exposed by the opening OP, a portion of the light emitting layer LEL disposed in the opening OP and a portion of the electrode E2 corresponding to the opening OP. In such condition, the range of a light emitting unit LU may for example be defined by the range of the portion of the light emitting layer LEL disposed in the opening OP, but not limited thereto. Therefore, the insulating layer IN6 may serve as the pixel defining layer and include a plurality of openings OP. Although FIG. 1 just shows a light emitting unit LU, the electronic device ED may include a plurality of light emitting units LU respectively be disposed in one of the openings OP of the insulating layer IN6. The electrode E1 may be electrically connected to the transistor T1 (for example, the drain electrode DE of the transistor T1), such that the light emitting unit LU may be electrically connected to the transistor T1. In other words, the light emitting unit LU may be disposed on at least one transistor (such as the transistor T1) and be electrically connected to the at least one transistor. It should be noted that although FIG. 1 just shows a light emitting unit LU, the electronic device ED may include a plurality of light emitting units LU, and each of the light emitting units LU may be disposed on at least one transistor and be electrically connected to a transistor respectively.

In some embodiments, the electronic device ED may further include an insulating layer IL1, an insulating layer OIL and an insulating layer IL2 disposed on the light emitting unit LU. Specifically, the insulating layer IL1, the insulating layer OIL and the insulating layer IL2 may be disposed on the electrode E2. The insulating layer IL1, the insulating layer OIL and the insulating layer IL2 may serve as an encapsulation layer to encapsulate the elements, the light emitting unit LU and the layers between the encapsulation layer and the substrate SB. In addition, the insulating layer IL2 may have a flat top surface to facilitate the disposition of other elements and layers on the insulating layer IL2. In the present embodiment, the insulating layer IL1 and the insulating layer IL2 may include any suitable transparent inorganic material, and the insulating layer OIL may include any suitable transparent organic material. In other words, the encapsulation layer mentioned above may be formed by alternately stacking inorganic insulating layers and organic insulating layers.

In some embodiments, as shown in FIG. 1, the electronic device ED may further include an insulating layer I1 disposed between the insulating layer IN5 and the insulating layer IL1 and an insulating layer 12 disposed on the insulating layer IL2. The insulating layer I1 and the insulating layer 12 may include any suitable insulating material. The insulating layer 12 may separate the optical unit LCU and the encapsulation layer (including the insulating layer IL1, the insulating layer OIL and the insulating layer IL2) and the elements or layers below the encapsulation layer. In such condition, the conductive layer M3 in the wire structure WS mentioned above may for example be electrically connected to the conductive layer M2 through the via penetrating the insulating layer 12, the insulating layer IL2, the insulating layer IL1, the insulating layer I1, the insulating layer IN5 and the insulating layer IN4, but not limited thereto.

In some embodiments, the electronic device ED may further include a dam wall structure DW1 disposed on the insulating layer IN5. The dam wall structure DW1 may be formed by patterning the insulating layer IN6. Specifically, the patterned insulating layer IN6 with a protruding shape may serve as the dam wall structure DW1, wherein the dam wall structure DW1 may be used to reduce the possibility of water and/or oxygen entering the interior of the electronic device ED, thereby protecting the electronic elements in the electronic device ED. The electrode E1, the light emitting layer LEL and the insulating layer IL1 may extend on the dam wall structure DW1, but not limited thereto. The dam wall structure DW1 may be disposed in the peripheral region NDA of the electronic device ED.

In some embodiments, a portion of the light emitting layer LEL disposed in one of the openings OP of the insulating layer IN6 may include a via V1, wherein the via V1 may expose a portion of the electrode E1, and the electrode E2 may be filled into the via V1 and contact the exposed portion of the electrode E1. In addition, the portion of the electrode E1 exposed by the via V1 may be electrically connected to the conductive layer M2 in the circuit layer CL, such that the portion of the electrode E1 may be electrically connected to the semiconductor SM through the conductive layer M2 and be electrically connected to the semiconductor OL through the semiconductor SM, but not limited thereto. Through the above-mentioned design, the electrode E1 and the electrode E2 may be electrically connected to a voltage source through the conductive layer M2, the semiconductor SM and the semiconductor OL, thereby reducing the impedance of the electrodes (that is, the electrode E1 and the electrode E2) of the light emitting unit LU, such that the performance of the light emitting unit LU may be improved. It should be noted that the portion of the light emitting layer LEL including the via V1 mentioned above may not serve as the light emitting region of the light emitting unit LU. In some embodiments, the portion of the electrode E1 exposed by the via V1 may be electrically connected to a voltage source through other suitable ways, which is not limited to the above-mentioned method.

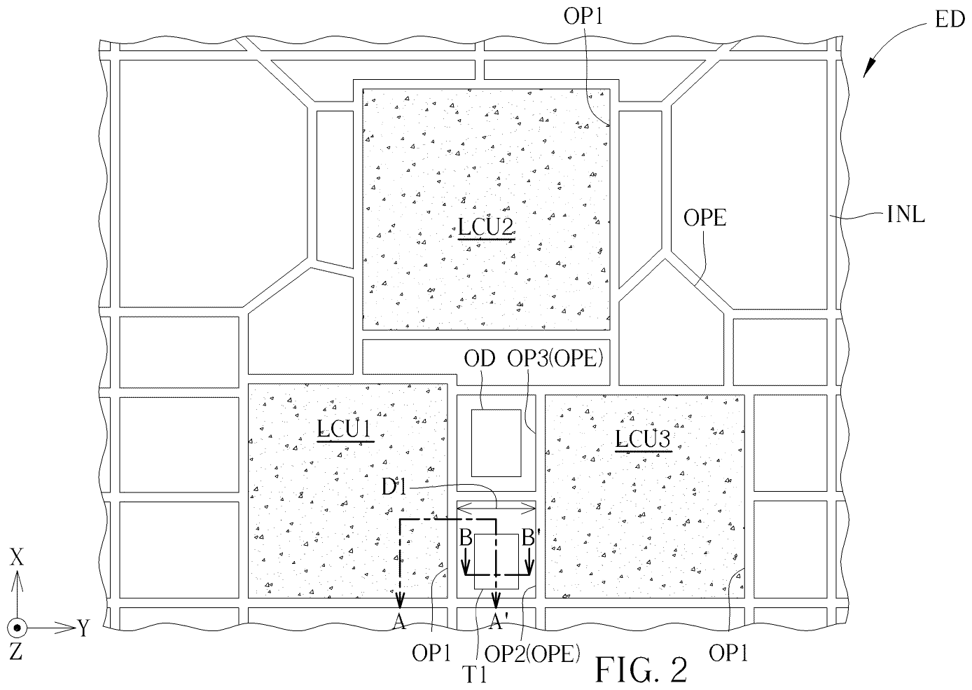

In the present embodiment, the optical unit LCU may be disposed on the insulating layer 12. The optical unit LCU may include any suitable material that can change the wavelength or color of the light passing through the optical unit LCU, or can change the light emitting angle of the light passing through the optical unit LCU. The optical unit LCU may include quantum dot, fluorescent, phosphorescent, scatting particle, other suitable materials or combinations of the above-mentioned materials. For example, the optical unit LCU of the present embodiment may include quantum dots QD, but not limited thereto. The optical unit LCU may be disposed corresponding to the light emitting unit LU. Specifically, the electronic device ED may further include an insulating layer INL disposed on the light emitting unit LU, wherein the insulating layer INL may include a first opening OP1, and the optical unit LCU may be disposed in the first opening OP1. In other words, the optical unit LCU may be formed by disposing the quantum dots QD in the first opening OP1 of the insulating layer INL in the present embodiment, but not limited thereto. The first opening OP1 may penetrate the insulating layer INL and expose the layer (such as the insulating layer 12, but not limited thereto) below the insulating layer INL. The insulating layer INL may include any suitable light shielding material, such as black resin, gray resin, scattering particle, other suitable materials or combinations of the above-mentioned materials. “The optical unit LCU is corresponding to the light emitting unit LU” mentioned above may represent that the optical unit LCU overlaps at least a portion of the light emitting unit LU in the top view of the electronic device ED. “The optical unit LCU overlaps at least a portion of the light emitting unit LU” described herein may represent that the optical unit LCU overlaps at least a portion of the light emitting layer LEL of the light emitting unit LU, but not limited thereto. In such condition, the first opening OP1 of the insulating layer INL may overlap at least a portion of the light emitting unit LU in the top view of the electronic device ED. The optical unit LCU may be used to change the wavelength or color of the light emitted by the light emitting unit LU to which the optical unit LCU corresponds, or the optical unit LCU may change the light emitting angle of the light emitted by the light emitting unit LU to which the optical unit LCU corresponds. It should be noted that although FIG. 1 just shows one optical unit LCU, the electronic device ED may include a plurality of optical units LCU, and each of the optical units LCU may be disposed in one of the first openings OP1 of the insulating layer INL and correspond to one of the light emitting units LU. In such condition, the insulating layer INL may include a plurality of first openings OP1, and the plurality of first openings OP1 may respectively overlap at least a portion of one of the light emitting units LU in the top view of the electronic device ED. The plurality of optical units LCU in the electronic device ED may make the lights have different wavelengths, colors or light emitting angles, but not limited thereto. For example, as shown in FIG. 2, the electronic device ED may include an optical unit LCU1, an optical unit LCU2 and an optical unit LCU3, and the lights passing through the optical unit LCU1, the optical unit LCU2 and the optical unit LCU3 respectively may become a red light, a green light and a blue light, which can be mixed into a white light, but not limited thereto. FIG. 1 just exemplarily shows the structure in which the optical unit LCU1 is disposed in the first opening OP1. In some embodiments, as shown in FIG. 1, the electronic device ED may further include a dummy optical unit DCU disposed in the peripheral region NDA, wherein the dummy optical unit DCU may not correspond to the light emitting unit LU. The dummy optical unit DCU may for example be disposed at a position adjacent to the active region DA in the peripheral region NDA, but not limited thereto.

According to the present disclosure, the insulating layer INL may further include a second opening OP2 in addition to the first opening OP1 mentioned above, wherein the optical unit LCU may not be disposed in the second opening OP2. Specifically, the insulating layer INL may include a plurality of openings, wherein a portion of the plurality of openings in which the optical unit LCU is disposed may be the first openings OP1 mentioned above, and another portion of the plurality of openings in which the optical unit LCU is not disposed may be openings OPE, wherein the second opening OP2 is one of the openings OPE. The second opening OP2 (or the opening OPE) may penetrate the insulating layer INL and expose the layer below the insulating layer INL. According to the present embodiment, the second opening OP2 of the insulating layer INL may overlap at least a portion of at least one transistor in the circuit layer CL in the top view of the electronic device ED. “The second opening OP2 overlaps at least a portion of the transistor” mentioned above may include the embodiment that the second opening OP2 overlaps at least one of the source electrode (or the source) and the drain electrode (or the drain) of the transistor in the top view of the electronic device ED. For example, as shown in FIG. 1, the insulating layer INL may include the second opening OP2 overlapped with the transistor T1, but not limited thereto. In such condition, the second opening OP2 may overlap at least one of the source electrode (not shown) and the drain electrode DE of the transistor T1 in the top view of the electronic device ED, or the second opening OP2 may overlap both the source electrode and the drain electrode DE of the transistor T1. The second opening OP2 may further overlap the gate electrode GE, the semiconductor SM and/or the semiconductor OL (if any) of the transistor T1, but not limited thereto. In other words, the electronic device ED of the present disclosure may include a plurality of transistors disposed on the substrate SB, a light emitting unit LU disposed on at least one of the plurality of transistors (such as the transistor T1) and an insulating layer INL disposed on the light emitting unit LU, wherein the insulating layer INL may include a first opening OP1 overlapping at least a portion of the light emitting unit LU and a second opening OP2 overlapping at least a portion of the at least one transistor (such as the transistor T1). It should be noted that “the opening OPE overlaps at least a portion of the transistor” described in the present disclosure may include the condition that at least one of the openings OPE overlaps at least a portion of the transistor. Specifically, in some embodiments, the insulating layer INL may include a plurality of openings OPE in which the optical unit LCU is not disposed, wherein a portion of the plurality of openings OPE (such as the second opening OP2) may overlap at least a portion of at least one transistor, and another portion of the plurality of openings OPE (such as another opening OPE shown in FIG. 1) may not overlap the transistor. In the present embodiment, at least a portion of each transistor in the circuit layer CL (that is, at least one of the source electrode and the drain electrode) may overlap at least one opening OPE (such as the second opening OP2) of the insulating layer INL in the top view of the electronic device ED), but not limited thereto. In some embodiments, the opening OPE may overlap at least a portion of other electronic elements in the top view of the electronic device ED, based on the design of the electronic device ED. The definition of the ranges of the source electrode and the drain electrode in the transistor will be detailed in the following.

In some embodiments, the electronic device ED may further include an insulating layer IN7, an insulating layer IN8 and an insulating layer IN9 disposed on the insulating layer INL. The insulating layer IN7, the insulating layer IN8 and the insulating layer IN9 may extend on the insulating layer INL and may be filled into the second opening OP2 (or the opening OPE). In other words, a portion of the insulating layer IN7, a portion of the insulating layer IN8 and a portion of the insulating layer IN9 may be disposed in the second opening OP2 (or the opening OPE). The insulating layer IN7 and the insulating layer IN9 may be inorganic layers and include any suitable transparent inorganic material. The insulating layer IN8 may be an organic layer and include any suitable transparent organic material or the material with low refractive index. In the present embodiment, the material of the insulating layer IN8 may have a lower refractive index than other organic layers (such as the insulating layer OIL, but not limited thereto) in the electronic device ED. Therefore, the light emitting effect of the electronic device ED may be improved and/or the interference caused by external ambient light entering the electronic devices ED may be reduced. In some embodiments, the electronic device ED may further include a dam wall structure DW2 disposed on the insulating layer IN7. The dam wall structure DW2 may be formed by patterning the insulating layer IN8. Specifically, the patterned insulating layer IN8 with a protruding shape may serve as the dam wall structure DW2, wherein the dam wall structure DW2 may be used to reduce the possibility of water and/or oxygen entering the interior of the electronic device ED. The insulating layer IN9 may extend on the dam wall structure DW2, but not limited thereto. The dam wall structure DW2 may be disposed in the peripheral region NDA of the electronic device ED.

According to the present embodiment, the electronic device ED may further include a first light filtering layer CF1, a second light filtering layer CF2 and a third light filtering layer CF3 disposed on the optical unit LCU (or the insulating layer INL), wherein the first light filtering layer CF1, the second light filtering layer CF2 and the third light filtering layer CF3 may respectively allow light of specific colors to pass through. The first light filtering layer CF1, the second light filtering layer CF2 and the third light filtering layer CF3 may for example include color filters, but not limited thereto. In the present embodiment, the first light filtering layer CF1, the second light filtering layer CF2 and the third light filtering layer CF3 may respectively allow a red light, a green light and a blue light to pass through, but not limited thereto. In other words, the first light filtering layer CF1, the second light filtering layer CF2 and the third light filtering layer CF3 may respectively include a red color filer, a green color filter and a blue color filter. In the present embodiment, the first light filtering layer CF1, the second light filtering layer CF2 and the third light filtering layer CF3 may be stacked to form a light filtering layer structure CFL. For example, as shown in FIG. 1, the first light filtering layer CF1, the second light filtering layer CF2 and the third light filtering layer CF3 may be sequentially disposed on the insulating layer IN9 to form the light filtering layer structure CFL. The disposition order of the first light filtering layer CF1, the second light filtering layer CF2 and the third light filtering layer CF3 in the light filtering layer structure CFL is exemplary, and it is not limited in the present embodiment. The light filtering layer structure CFL may extend on the insulating layer INL and may be filled into the second opening OP2 (or the opening OPE) of the insulating layer INL. Specifically, as shown in FIG. 1, the first light filtering layer CF1, the second light filtering layer CF2 and the third light filtering layer CF3 may be filled into the second opening OP2 (or the opening OPE) of the insulating layer INL, that is, a portion of the first light filtering layer CF1, a portion of the second light filtering layer CF2 and a portion of the third light filtering layer CF3 may be disposed in the second opening OP2 (or the opening OPE). In addition, in the present embodiment, a portion of the light filtering layer structure CFL corresponding to an optical unit LCU may only include the light filtering layer that has the same color as the light after it passing through the optical unit LCU. “The portion of the light filtering layer structure CFL corresponding to an optical unit LCU” described herein may be the portion of the light filtering layer structure CFL overlapped with the optical unit LCU in the top view of the electronic device ED. For example, as shown in FIG. 1, the light passing through the optical unit LCU1 may become a red light, and the portion of the light filtering layer structure CFL corresponding to the optical unit LCU1 may only include the red color filter, that is, the first light filtering layer CF1. Specifically, in the portion of the light filtering layer structure CFL corresponding to the optical unit LCU1, the second light filtering layer CF2 and the third light filtering layer CF3 may be removed (for example, through the patterning processes of the second light filtering layer CF2 and the third light filtering layer CF3), such that the optical unit LCU1 may only correspond to the first light filtering layer CF1 of the light filtering layer structure CFL. In such condition, an opening corresponding to the optical unit LCU1 may be formed after removing a portion of the second light filtering layer CF2 and a portion of the third light filtering layer CF3. In short, taking the structure shown in FIG. 1 as an example, the electronic device ED may include the first light filtering layer CF1, the second light filtering layer CF2 and the third light filtering layer CF3 disposed on the insulating layer INL, a portion of the first light filtering layer CF1, a portion of the second light filtering layer CF2 and a portion of the third light filtering layer CF3 may be disposed in the second opening OP2, and in the top view of the electronic device ED, the first light filtering layer CF1 may overlap the optical unit LCU1, and the second light filtering layer CF2 and the third light filtering layer CF3 may not overlap the optical unit LCU1. Similarly, when the light passes through the optical unit LCU2 shown in FIG. 1 and becomes a green light, the portion of the light filtering layer structure CFL corresponding to the optical unit LCU2 may only include the second light filtering layer CF2, that is, the first light filtering layer CF1 and the third light filtering layer CF3 may not correspond to the optical unit LCU2; and when the light passes through the optical unit LCU3 shown in FIG. 1 and becomes a blue light, the portion of the light filtering layer structure CFL corresponding to the optical unit LCU3 may only include the third light filtering layer CF3, that is, the first light filtering layer CF1 and the second light filtering layer CF2 may not correspond to the optical unit LCU3. It should be noted that a portion of the light filtering layer structure CFL corresponding to the dummy optical unit DCU located in the peripheral region NDA may include the first light filtering layer CF1, the second light filtering layer CF2 and the third light filtering layer CF3, that is, the light filtering layers of the portion of the light filtering layer structure CFL may not be removed.

According to the present embodiment, the electronic device ED may further include a protecting layer disposed on the light filtering layer structure CFL. The protecting layer may be the combination of the layers located on the light filtering layer structure CFL, or the protecting layer may include the structure formed by stacking the layers on the light filtering layer structure CFL. As shown in FIG. 1, the protecting layer of the electronic device ED of the present embodiment may include an optical layer OC, an adhesive layer AD, a cover layer CO and an anti-reflection layer AR, but not limited thereto. The optical layer OC may be disposed on the light filtering layer structure CFL, and the adhesive layer AD may be disposed on the optical layer OC. The optical layer OC may include any suitable element or layer that can improve the light emitting effect of the electronic device ED. The adhesive layer AD may include any suitable transparent adhesive material. The cover layer CO may be attached to the optical layer OC through the adhesive layer AD. The cover layer CO may provide protection to the layers or elements there below. The cover layer CO may for example include glass, but not limited thereto. The anti-reflection layer AR may be disposed on the cover layer CO to improve the light emitting effect of the electronic device ED. Some of the layers of the protecting layer may be filled into the second opening OP2 (or the opening OPE) of the insulating layer INL. For example, as shown in FIG. 1, a portion of the optical layer OC of the protecting layer may be filled into the second opening OP2 (or the opening OPE). It should be noted that the layers included in the protecting layer shown in FIG. 1 are exemplary, it is not limited in the present disclosure. In other embodiments, the protecting layer may include other suitable elements or layers according to the design of the electronic device ED. In addition, although it is not shown in FIG. 1, the electronic device ED may further include a touch layer in some embodiments, wherein the touch layer may be disposed at any suitable position in the electronic device ED.

Referring to FIG. 2 and FIG. 3, FIG. 2 schematically illustrates a partial top view of an electronic device according to a second embodiment of the present disclosure, and FIG. 3 schematically illustrates a cross-sectional view of a transistor of the electronic device according to the second embodiment of the present disclosure. In order to simplify the figure, FIG. 2 just shows the partial structure of the insulating layer INL. Specifically, FIG. 2 shows the disposition of one optical unit LCU1, one optical unit LCU2 and one optical unit LCU3 in the openings of the insulating layer INL. As mentioned above, the insulating layer INL may be patterned to form a plurality of openings, and the plurality of openings may be divided into the first openings OP1 in which the optical unit LCU is disposed and the openings OPE in which the optical unit LCU is not disposed. Therefore, in the partial top view of the insulating layer INL shown in FIG. 2, the insulating layer INL may include three first openings OP1, wherein the optical unit LCU1, the optical unit LCU2 and the optical unit LCU3 are respectively disposed in these three first openings OP1, and other openings of the insulating layer INL in which the optical unit LCU is not disposed may be the openings OPE. The openings OPE may include the second opening OP2, and in the top view of the electronic device ED, the second opening OP2 may overlap at least a portion of the transistor in the circuit layer CL. For example, FIG. 2 shows a situation in which the second opening OP2 overlaps the transistor T1 in the top view of the electronic device ED. In such condition, a portion of the structure shown in FIG. 1 may correspond to the cross-sectional structure of the top view structure shown in FIG. 2 along a section line A-A′. It should be noted that although it is not shown in FIG. 2, the electronic device ED may include another transistor, and another opening OPE may overlap at least a portion of the another transistor in the top view of the electronic device ED. In some embodiments, some of the openings OPE may not overlap the transistor. The pattern of the insulating layer INL shown in FIG. 2 is exemplary, it is not limited in the present embodiment. In other embodiments, the insulating layer INL may include any suitable pattern according to the design of the electronic device ED (such as the disposition positions of the optical units LCU or the transistors), thereby forming the first openings OP1 for disposing the optical units LCU and the openings OPE (such as the second opening OP2) overlapped with at least a portion of the transistors.

FIG. 3 shows the cross-sectional structure of one transistor (such as the transistor T1) in the electronic device ED. Specifically, the structure shown in FIG. 3 may be the cross-sectional structure of the structure shown in FIG. 2 along a section line B-B′. As shown in FIG. 3, the transistor T1 may include the semiconductor SM, the gate electrode GE, the source electrode SE and the drain electrode DE, but not limited thereto. In some embodiments, the transistor T1 may further include the semiconductor OL electrically connected to the semiconductor SM. The gate electrode GE may be formed of the conductive layer M1, and the source electrode SE and the drain electrode DE may be formed of the conductive layer M2, but not limited thereto. In the present embodiment, the electronic device ED may further include a plurality of data lines and a plurality of scan lines (not shown), wherein one of the plurality of scan lines may be electrically connected to the gate electrode GE, or the scan lines and the gate electrode GE may both be formed by patterning the conductive layer M1. One of the plurality of data lines may be electrically connected to the source electrode SE, or the data lines and the source electrode SE may both be formed by patterning the conductive layer M2. The plurality of scan lines may extend in a direction, wherein the extending direction of the scan lines may be the extending direction of the conductive layer M1 used to form the gate electrode GE of the transistor T1. For example, in the present embodiment, the extending direction of the conductive layer M1 used to form the gate electrode GE of the transistor T1 may be parallel to the direction X, that is, the extending direction of the scan lines may be parallel to the direction X, but not limited thereto. The plurality of data lines may extend in another direction not parallel to the extending direction of the scan lines. According to the present embodiment, the ranges of the gate electrode GE, the source electrode SE and the drain electrode DE in the transistor T1 may be defined in the cross-sectional view of the transistor T1. Specifically, the gate electrode GE, the source electrode SE and the drain electrode DE of the transistor T1 may be defined in a cross-sectional view of the transistor T1 perpendicular to the extending direction of the scan lines (that is, the direction Y). FIG. 3 is used as an example to illustrate the definition of the ranges of the gate electrode GE, the source electrode SE and the drain electrode DE of the transistor T1 in the following, wherein FIG. 3 shows the cross-sectional view of the transistor T1 perpendicular to the extending direction of the scan lines (that is, the direction Y).

According to the present embodiment, the gate electrode GE of the transistor T1 may have a range RG in the cross-sectional view of the transistor T1, wherein the range RG of the gate electrode GE may be defined by the range R1 of the portion of the conductive layer M1 overlapping the semiconductor SM. Specifically, in the cross-sectional view of the transistor T1 perpendicular to the extending direction of the scan lines, the range R1 of the portion of the conductive layer M1 overlapping the semiconductor SM may be confirmed at first, and the width DG of the range R1 may be measured. The width DG may be the maximum width of the range R1 measured in a direction perpendicular to the extending direction of the scan lines (that is, the direction Y). After that, the range RG of the gate electrode GE may be defined by extending the range R1 toward its left side and right side by 0.25 times the width (that is, the width DG) of the range R1. In other words, in the cross-sectional view of the transistor T1, the left side and right side of the range RG may respectively protrude from the left side and right side of the range R1 by a distance of 0.25 times the width DG of the range R1. In such condition, the range RG may have a width D3, and the width D3 may be 1.5 times the width DG (that is D3=1.5DG). The width D3 may be the maximum width of the range RG measured in a direction perpendicular to the extending direction of the scan lines (that is, the direction Y). The width D3 may also be regarded as the width of the gate electrode GE. The range RG of the gate electrode GE of the transistor T1 may be defined through the above-mentioned way.

According to the present embodiment, the source electrode SE of the transistor T1 may have a range RS in the cross-sectional view of the transistor T1, wherein the range RS of the source electrode SE may be defined by the range R3 of the portion of the conductive layer M2 contacting the source region SR of the semiconductor SM. Specifically, in the cross-sectional view of the transistor T1 perpendicular to the extending direction of the scan lines, the range R3 of the portion of the conductive layer M2 overlapping the source region SR of the semiconductor SM may be confirmed at first, and the width DS of the range R3 may be measured. The width DS may be the maximum width of the range R3 measured in a direction perpendicular to the extending direction of the scan lines (that is, the direction Y). Specifically, the width DS may be the width measured at the side of the conductive layer M2 contacting the source region SR of the semiconductor SM. After that, the range RS of the source electrode SE may be defined by extending the range R3 toward its left side and right side by 0.25 times the width (that is, the width DS) of the range R3. In other words, in the cross-sectional view of the transistor T1, the left side and right side of the range RS may respectively protrude from the left side and right side of the range R3 by a distance of 0.25 times the width DS of the range R3. In such condition, the range RS may have a width D4, and the width D4 may be 1.5 times the width DS (that is D4=1.5DS). The width D4 may be the maximum width of the range RS measured in a direction perpendicular to the extending direction of the scan lines (that is, the direction Y). The width D4 may also be regarded as the width of the source electrode SE. The range RS of the source electrode SE of the transistor T1 may be defined through the above-mentioned way.

According to the present embodiment, the drain electrode DE of the transistor T1 may have a range RD in the cross-sectional view of the transistor T1, wherein the range RD of the drain electrode DE may be defined by the range R2 of the portion of the conductive layer M2 contacting the drain region DR of the semiconductor SM. Specifically, in the cross-sectional view of the transistor T1 perpendicular to the extending direction of the scan lines, the range R2 of the portion of the conductive layer M2 overlapping the drain region DR of the semiconductor SM may be confirmed at first, and the width DRD of the range R2 may be measured. The width DRD may be the maximum width of the range R2 measured in a direction perpendicular to the extending direction of the scan lines (that is, the direction Y). Specifically, the width DRD may be the width measured at the side of the conductive layer M2 contacting the drain region DR of the semiconductor SM. After that, the range RD of the drain electrode DE may be defined by extending the range R2 toward its left side and right side by 0.25 times the width (that is, the width DRD) of the range R2. In other words, in the cross-sectional view of the transistor T1, the left side and right side of the range RD may respectively protrude from the left side and right side of the range R2 by a distance of 0.25 times the width DRD of the range R2. In such condition, the range RD may have a width D2, and the width D2 may be 1.5 times the width DRD (that is D2=1.5DRD). The width D2 may be the maximum width of the range RD measured in a direction perpendicular to the extending direction of the scan lines (that is, the direction Y). The width D2 may also be regarded as the width of the drain electrode DE. The range RD of the drain electrode DE of the transistor T1 may be defined through the above-mentioned way.

After the ranges of the gate electrode GE, the source electrode SE and the drain electrode DE of the transistor T1 are defined, “the second opening OP2 overlaps at least one of the drain electrode DE and the source electrode SE in the transistor T1” mentioned above may represent that when viewing from a top view direction of the electronic device ED or in a cross-sectional view of the electronic device ED (for example, the cross-sectional view perpendicular to the extending direction of the scan lines), the projection of the second opening OP2 on the substrate SB may overlap at least one of the projection of the range RD of the drain electrode DE on the substrate SB and the projection of the range RS of the source electrode SE on the substrate SB, or the range of the projection of the second opening OP2 on the substrate SB may cover at least one of the projection of the range RD on the substrate SB and the projection of the range RS on the substrate SB. It should be noted that the above-mentioned definition of the gate electrode GE, the source electrode SE and the drain electrode DE of the transistor T1 may be applied to other transistors in the circuit layer CL. In the present disclosure, when describing another opening (such as the opening OPE) of the insulating layer INL overlapping at least a portion of the transistor or describing one element overlapping another element, the definition of “overlap” may refer to the contents mentioned above, and will not be redundantly described.

According to the present embodiment, as shown in FIG. 2, the second opening OP2 may have a width D1, wherein the width D1 may be the width of the second opening OP2 measured in a direction parallel to the extending direction of the scan lines (that is, parallel to the direction X). That is, the extending direction of the width D1 may be perpendicular to the direction X, and may for example parallel to the direction Y, but not limited thereto. Specifically, in a top view (for example, FIG. 2) of the insulating layer INL, the width D1 may be defined as the maximum width of the second opening OP2 measured in a direction parallel to the extending direction of the scan lines, but not limited thereto. In such condition, the width D1 of the second opening OP2, the width D2 of the drain electrode DE of the transistor T1, the width D3 of the gate electrode GE of the transistor T1 and the width D4 of the source electrode SE of the transistor T1 may be the widths measured in the same direction (that is, parallel to the direction X). According to the present embodiment, the width D1 of the second opening OP2 may range from 15 micrometers (μm) to 45 μm (that is, 15 μm<D1<45 μm), but not limited thereto. In some embodiments, the width D1 of the second opening OP2 may range from 20 μm to 40 μm (that is, 20 μm<D1<40 μm). The definition and range of the width of other openings OPE of the insulating layer INL may refer to the width D1 of the second opening OP2 mentioned above. When the width D1 of the second opening OP2 is less than 15 μm, the size of the second opening OP2 may be too small, thereby increasing the difficulty of overlapping the second opening OP2 with the transistor T1. When the width D1 of the second opening OP2 is greater than 45 μm, the size of the second opening OP2 may be too large, thereby reducing the light-shielding effect of the insulating layer INL.

In some embodiments, the second opening OP2 shown in FIG. 2 may overlap the gate electrode GE of the transistor T1, and the width D1 of the second opening OP2 may be greater than the width D3 of the gate electrode GE of the transistor T1 (that is, D1>D3). In some embodiments, the second opening OP2 shown in FIG. 2 may overlap the source electrode SE of the transistor T1, and the width D1 of the second opening OP2 may be greater than the width D4 of the source electrode SE of the transistor T1 (that is, D1>D4). In some embodiments, the second opening OP2 shown in FIG. 2 may overlap the drain electrode DE of the transistor T1, and the width D1 of the second opening OP2 may be greater than the width D2 of the drain electrode DE of the transistor T1 (that is, D1>D2). In some embodiments, the width D1 of the second opening OP2 may be greater than the sum of the width D2, the width D3 and the width D4 (that is, D1>D2+D3+D4). In such condition, the second opening OP2 may for example overlap the gate electrode GE, the source electrode SE and the drain electrode DE of the transistor T1 at the same time. It should be noted that the relationship between the width D1 of the second opening OP2 and the width D3 of the gate electrode GE, the width D2 of the drain electrode DE and the width D4 of the source electrode SE of the transistor T1 overlapping the second opening OP2 mentioned above may be applied to the width of another opening (such as the openings OPE, but not limited thereto) of the insulating layer INL and the widths of the gate electrode, the drain electrode and the source electrode of the transistor overlapping the another opening.

Return to FIG. 1, according to the present embodiment, the second opening OP2 of the insulating layer INL may have a depth DH, wherein the depth DH may be defined as the maximum vertical distance between the top surface and the bottom surface of the portion of the insulating layer INL adjacent to the second opening OP2, but not limited thereto. In some embodiments, the depth DH may range from 4 μm to 13 μm (that is, 4 μm<DH<13 μm). In some embodiments, the depth DH may range from 6 μm to 10 μm (that is, 6 μm<DH<10 μm).

In some embodiments, the electronic device ED may include a conductive layer ML disposed on the buffer layer BF and an insulating layer IN0 disposed on the conductive layer ML, but not limited thereto. The conductive layer ML may form a capacitor with the conductive layer M1 or the conductive layer M2, but not limited thereto. The insulating layer IN0 may include any suitable insulating material. In some embodiments, the electronic device ED may not include the insulating layer IN0 and the conductive layer ML. In addition, as shown in FIG. 3, in the present embodiment, the semiconductor SM may be electrically connected to the semiconductor OL through a contact element CT. The contact element CT may be formed of any suitable conductive layer in the circuit layer CL. The features of other elements or layers shown in FIG. 3 may refer to the contents mentioned above, and will not be redundantly described.

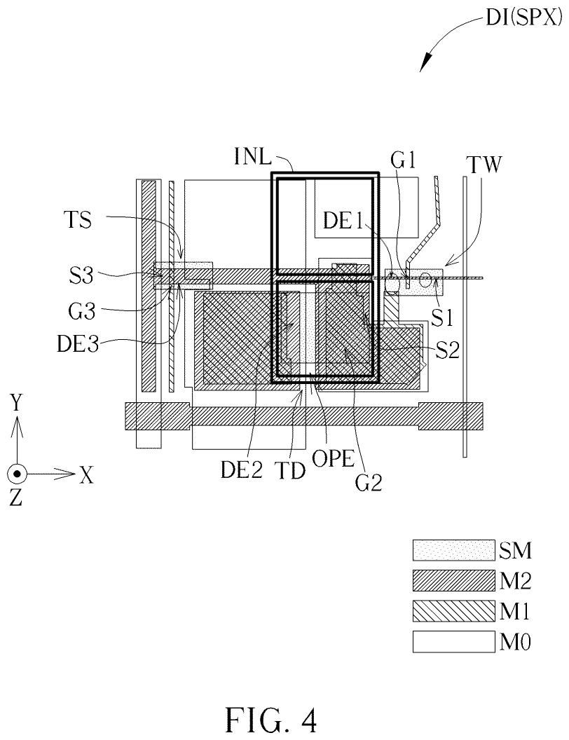

Referring to FIG. 4, FIG. 4 schematically illustrates a partial top view of an electronic device according to a third embodiment of the present disclosure. Specifically, FIG. 4 for example shows a top view of the driving circuit D1 of a sub-pixel SPX. In detail, in the present embodiment, an optical unit LCU, the light filtering layer (one of the first light filtering layer CF1, the second light filtering layer CF2 and the third light filtering layer CF3) to which the optical unit LCU corresponds, at least one light emitting unit LU and the driving circuit D1 (including at least one transistor) used for driving the at least one light emitting unit LU may be regarded as a sub-pixel SPX. In such condition, the optical unit LCU1, the optical unit LCU2 and the optical unit LCU3 mentioned above may respectively form a red sub-pixel SPX, a green sub-pixel SPX and a blue sub-pixel SPX, and the three sub-pixels may form a pixel. The driving circuit D1 shown in FIG. 4 may be the driving circuit D1 of any one of the red sub-pixel SPX, the green sub-pixel SPX and the blue sub-pixel SPX. In the present embodiment, as shown in FIG. 4, the driving circuit D1 of a sub-pixel SPX may for example include three transistors, which are respectively the switch transistor TW, the driving transistor TD and the sensing transistor TS, but not limited thereto. The switch transistor TW may include a gate electrode G1, a source electrode S1 and a drain electrode DE1, the driving transistor TD may include a gate electrode G2, a source electrode S2 and a drain electrode DE2, and the sensing transistor TS may include a gate electrode G3, a source electrode S3 and a drain electrode DE3. It should be noted that the number of the transistors included in the driving circuit D1 shown in FIG. 4 is exemplary, it is not limited in the present embodiment. In other embodiments, the driving circuit D1 may include transistors of any suitable number according to the design of the driving circuit D1.

Several examples of the overlapping relationship between the opening OPE of the insulating layer INL and the transistor will be described in the following.

In some embodiments, one opening OPE of the insulating layer INL (which may be the above-mentioned second opening OP2, but not limited thereto) may overlap at least a portion of one transistor in the top view of the electronic device ED. For example, as shown in FIG. 4, one opening OPE of the insulating layer INL may overlap the gate electrode G2, the source electrode S2 and the drain electrode DE2 of the driving transistor TD, that is, the opening OPE overlaps the driving transistor TD. In some embodiments, one opening OPE of the insulating layer INL may overlap at least one of the source electrode S2 and the drain electrode DE2 of the driving transistor TD. It should be noted that FIG. 4 just exemplarily shows a portion of the insulating layer INL, and the insulating layer INL may include other openings OPE overlapped with at least a portion of the switch transistor TW and/or the sensing transistor TS.

In some embodiments, one opening OPE of the insulating layer INL (which may be the above-mentioned second opening OP2, but not limited thereto) may overlap at least portions of a plurality of transistors in the top view of the electronic device ED. For example, one opening OPE of the insulating layer INL may overlap the gate electrode G2, the source electrode S2 and the drain electrode DE2 of the driving transistor TD, the gate electrode G1, the source electrode S1 and the drain electrode DE1 of the switch transistor TW and the gate electrode G3, the source electrode S3 and the drain electrode DE3 of the sensing transistor TS at the same time, but not limited thereto. In some embodiments, one opening OPE of the insulating layer INL may overlap at least a portion of any two of the switch transistor TW, the driving transistor TD and the sensing transistor TS. In some embodiments, one opening OPE of the insulating layer INL may overlap a plurality of transistors in a plurality of driving circuits D1.

In some embodiments, one transistor may overlap a plurality of openings OPE in the top view of the electronic device ED. “A transistor overlaps a plurality of openings OPE” described herein may for example include the embodiment that the source electrode SE (or the drain electrode DE) of the transistor overlaps the plurality of openings OPE and the embodiments that the source electrode SE and the drain electrode DE of the transistor respectively overlap different openings OPE. For example, in the driving circuit D1, the source electrode S1 and the drain electrode DE1 of the switch transistor TW may overlap different openings OPE, the source electrode S2 and the drain electrode DE2 of the driving transistor TD may overlap different openings OPE, and the source electrode S3 and the drain electrode DE3 of the sensing transistor TS may overlap different openings OPE, but not limited thereto.

The above-mentioned overlapping ways of the opening OPE of the insulating layer INL and the transistor may be applied to the embodiments and variant embodiments of the present disclosure. It should be noted that different openings OPE of the insulating layer INL may overlap the transistors in different ways.

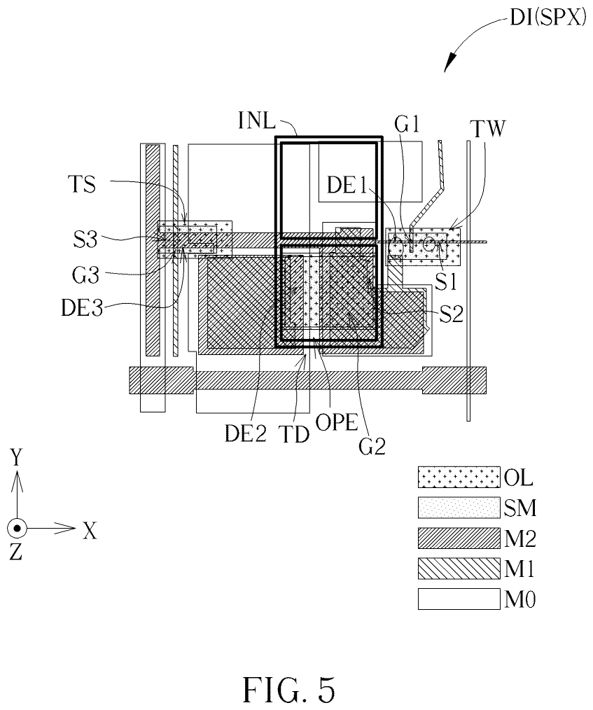

Referring to FIG. 5, FIG. 5 schematically illustrates a partial top view of an electronic device according to a fourth embodiment of the present disclosure. One of the main differences between the structure shown in FIG. 5 and the structure shown in FIG. 4 is that the driving transistor TD, the switch transistor TW and the sensing transistor TS shown in FIG. 5 further include the semiconductor OL respectively. According to the present embodiment, the opening OPE of the insulating layer INL may overlap the semiconductor OL in the transistor in the top view of the electronic device ED. In some embodiments, one opening OPE of the insulating layer INL (which may be the above-mentioned second opening OP2, but not limited thereto) may overlap the semiconductor OL of one transistor in the top view of the electronic device ED. For example, as shown in FIG. 5, one opening OPE of the insulating layer INL may overlap the semiconductor OL of the driving transistor TD. In some embodiments, one opening OPE of the insulating layer INL (which may be the above-mentioned second opening OP2, but not limited thereto) may overlap the semiconductors OL of a plurality of transistors in the top view of the electronic device ED. For example, one opening OPE of the insulating layer INL may overlap the semiconductor OL of the driving transistor TD, the semiconductor OL of the switch transistor TW and the semiconductor OL of the sensing transistor TS at the same time. In some embodiments, one opening OPE of the insulating layer INL may overlap the semiconductors OL of a plurality of transistors in a plurality of driving circuits D1. In some embodiments, the semiconductor OL in a transistor may overlap a plurality of openings OPE in the top view of the electronic device ED. For example, the semiconductor OL of the driving transistor TD, the semiconductor OL of the switch transistor TW and the semiconductor OL of the sensing transistor TS may overlap more than one opening OPE respectively, but not limited thereto. The above-mentioned overlapping ways of the opening OPE of the insulating layer INL and the semiconductor OL of the transistor may be applied to the embodiments and variant embodiments of the present disclosure. It should be noted that different openings OPE may overlap the semiconductors OL in different ways.

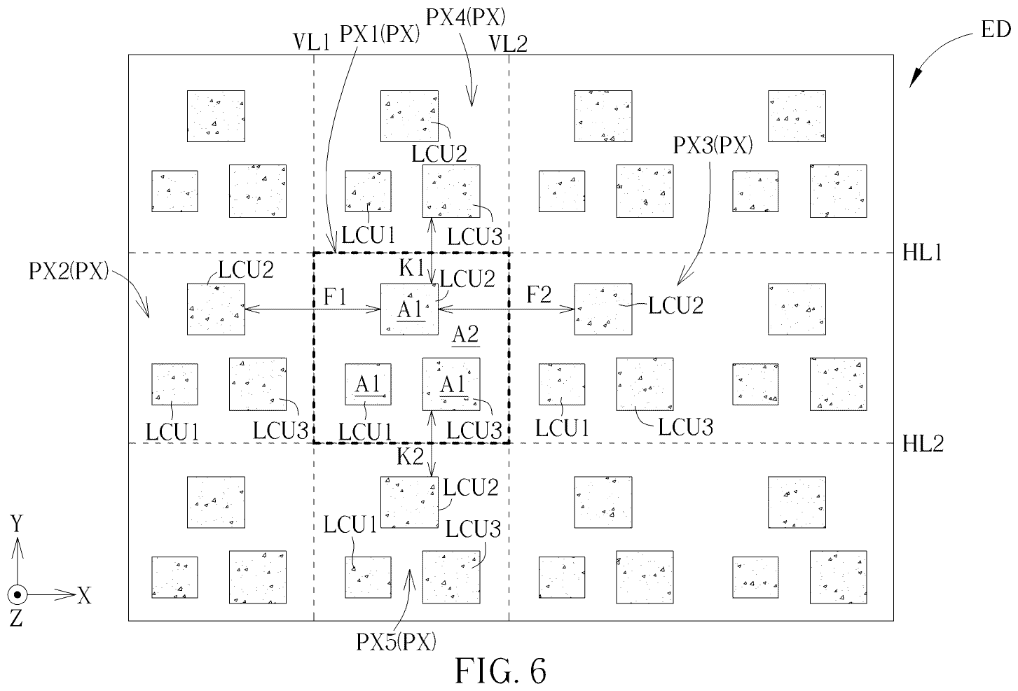

Referring to FIG. 6, FIG. 6 schematically illustrates a partial top view of an electronic device according to a fifth embodiment of the present disclosure. Specifically, FIG. 6 shows the arrangement of a plurality of pixels PX in the electronic device ED. In the present embodiment, each pixel PX may be formed of three sub-pixels (that is, the sub-pixel SPX mentioned above), and these three sub-pixels may respectively include the optical unit LCU1, the optical unit LCU2 and the optical unit LCU3, but not limited thereto. In other embodiments, the number of the sub-pixels (or optical units LCU) included in a pixel may be determined according to the design of the electronic device ED. In the present embodiment, the range of a pixel PX may be defined through the following way. First, in a horizontal direction (for example, the direction X), two adjacent optical units LCU with the same color which are located in two adjacent pixels PX respectively may be confirmed. “The two adjacent optical units LCU” described herein may represent that no other optical unit LCU is included between the two optical units LCU. For example, in FIG. 6, the optical unit LCU2 in the pixel PX1 and the optical unit LCU2 in the pixel PX2 adjacent to the pixel PX1 and located at the left side of the pixel PX1 may be two optical units LCU adjacent to each other and having the same color. Similarly, the optical unit LCU2 in the pixel PX1 and the optical unit LCU2 in the pixel PX3 adjacent to the pixel PX1 and located at the right side of the pixel PX1 may also be two optical units LCU adjacent to each other and having the same color. After the “two adjacent optical units LCU having the same color” mentioned above are confirmed, a virtual line passing through the midpoint of the two optical units LCU may be defined. Specifically, taking the pixel PX1 as an example, a virtual line VL1 may be defined by the optical unit LCU2 in the pixel PX1 and another optical unit LCU2 located at the left side of the optical unit LCU2 in the pixel PX1 (that is, the optical unit LCU2 in the pixel PX2), wherein the virtual line VL1 may extend along a vertical direction perpendicular to the horizontal direction (such as the direction Y) and pass through the midpoint of the optical unit LCU2 in the pixel PX1 and the optical unit LCU2 in the pixel PX2. In such condition, a distance F1 may be included between the optical unit LCU2 in the pixel PX1 and the optical unit LCU2 in the pixel PX2 in the horizontal direction, and a distance from the virtual line VL1 to the optical unit LCU2 in the pixel PX1 and a distance from the virtual line VL1 to the optical unit LCU2 in the pixel PX2 may both be half of the distance F1. Similarly, a virtual line VL2 may be defined by the optical unit LCU2 in the pixel PX1 and another optical unit LCU2 located at the right side of the optical unit LCU2 in the pixel PX1 (that is, the optical unit LCU2 in the pixel PX3), wherein the virtual line VL2 may extend along the vertical direction and pass through the midpoint of the optical unit LCU2 in the pixel PX1 and the optical unit LCU2 in the pixel PX3. In such condition, a distance F2 may be included between the optical unit LCU2 in the pixel PX1 and the optical unit LCU2 in the pixel PX3 in the horizontal direction, and a distance from the virtual line VL2 to the optical unit LCU2 in the pixel PX1 and a distance from the virtual line VL2 to the optical unit LCU2 in the pixel PX3 may both be half of the distance F2. In other words, a pixel PX and another two pixels PX respectively located at the left side and the right side of the pixel PX may respectively define a virtual line. The distance F1 and the distance F2 may be the same or different, it is not limited in the present embodiment. In addition, in the vertical direction, two optical units LCU with the minimum vertical distance and respectively located in two adjacent pixels PX may be confirmed at first. For example, in FIG. 6, the optical unit LCU2 in the pixel PX1 and the optical unit LCU3 in the pixel PX4 adjacent to the pixel PX1 and located above the pixel PX1 may be the optical units LCU respectively located in two adjacent pixels PX and having the minimum vertical distance. Similarly, the optical unit LCU3 in the pixel PX1 and the optical unit LCU2 in the pixel PX5 adjacent to the pixel PX1 and located below the pixel PX1 may also be the optical units LCU respectively located in two adjacent pixels PX and having the minimum vertical distance. After “the two optical units LCU respectively located in two adjacent pixels PX and having the minimum vertical distance” are confirmed, a virtual line passing through the midpoint of the two optical units LCU may be defined. Specifically, taking the pixel PX1 as an example, a virtual line HL1 may be defined by the optical unit LCU2 in the pixel PX1 and the optical unit LCU3 in the pixel PX4 above the pixel PX1, wherein the virtual line HL1 may extend along the horizontal direction and pass through the midpoint of the optical unit LCU2 in the pixel PX1 and the optical unit LCU3 in the pixel PX4. In such condition, a distance K1 may be included between the optical unit LCU2 in the pixel PX1 and the optical unit LCU3 in the pixel PX4 in the vertical direction, and a distance from the virtual line HL1 to the optical unit LCU2 in the pixel PX1 and a distance from the virtual line HL1 to the optical unit LCU3 in the pixel PX4 may both be half of the distance K1. Similarly, a virtual line HL2 may be defined by the optical unit LCU3 in the pixel PX1 and the optical unit LCU2 in the pixel PX5 below the pixel PX1, wherein the virtual line HL2 may extend along the horizontal direction and pass through the midpoint of the optical unit LCU3 in the pixel PX1 and the optical unit LCU2 in the pixel PX5. In such condition, a distance K2 may be included between the optical unit LCU3 in the pixel PX1 and the optical unit LCU2 in the pixel PX5 in the vertical direction, and a distance from the virtual line HL2 to the optical unit LCU3 in the pixel PX1 and a distance from the virtual line HL2 to the optical unit LCU2 in the pixel PX5 may both be half of the distance K2. In other words, a pixel PX and another two pixels PX respectively located above the pixel PX and below the pixel PX may respectively define a virtual line. The distance K1 and the distance K2 may be the same or different, it is not limited in the present embodiment. According to the present embodiment, after two virtual lines VL1 and VL2 and two virtual lines HL1 and HL2 are defined according to a pixel, the region of the pixel may be defined as the region enclosed by the two virtual lines VL1 and VL2 and the two virtual lines HL1 and HL2, but not limited thereto. For example, in FIG. 6, the region of the pixel PX1 may be the region enclosed by the virtual line VL1, the virtual line VL2, the virtual line HL1 and the virtual line HL2. Therefore, the range of the region of the pixel PX may be defined. It should be noted that the definition of the region of the pixel PX mentioned above is exemplary, it is not limited in the present disclosure. In other embodiments, the region of the pixel PX may be defined in any suitable way according to the arrangement of the pixels PX and/or the disposition positions of the optical units LCU.

In the present embodiment, the region of a pixel PX may include a first area A1 and a second area A2, wherein the first area A1 corresponds to the optical unit LCU, and the second area A2 does not correspond to the optical unit LCU. In other words, the first area A1 may be defined as the portion of the region of a pixel PX corresponding to the optical unit LCU, and the second area A2 may be defined as another portion of the region of a pixel PX not corresponding to the optical unit LCU, that is, the second area A2 may be another portion of the region of a pixel PX other than the first area A1. The first area A1 may include three portions respectively corresponding to the optical unit LCU1, the optical unit LCU2 and the optical unit LCU3 in the pixel PX, but not limited thereto. According to the present embodiment, in the top view of the electronic device ED, the number of transistors in the circuit layer CL overlapping the first area A1 may be less than the number of transistors in the circuit layer CL overlapping the second area A2. “The transistor overlaps the first area A1 (or the second area A2)” described herein may represent that at least a portion of the transistor (for example, at least one of the source electrode and the drain electrode) overlaps the first area A1 (or the second area A2). For example, in the top view of the electronic device ED, the circuit layer CL may include X1 transistors overlapping the first area A1 of a pixel PX and Y1 transistors overlapping the second area A2 of the pixel PX, wherein X1 may be less than Y1. The above-mentioned relationship between the numbers of the transistors overlapping the first area A1 and the second area A2 respectively may be applied to each pixel PX. In addition, as mentioned above, the insulating layer INL may include the first opening OP1 in which the optical unit LCU is disposed and the opening OPE in which the optical unit LCU is not disposed. In such condition, the first opening OP1 may correspond to the first area A1, and the opening OPE may correspond to the second area A2. Specifically, the first area A1 of a pixel PX may correspond to three first openings OP1, which are respectively used to dispose the optical unit LCU1, the optical unit LCU2 and the optical unit LCU3. In some embodiments, the second area A2 of a pixel PX may correspond to one opening OPE. In such condition, in the top view of the electronic device ED, the sum of the numbers of the transistors overlapped with the three first openings OP1 to which the first area A1 of a pixel PX corresponds may be less than the number of the transistors overlapped with the opening OPE to which the second area A2 of the pixel PX corresponds. In some embodiments, the second area A2 of a pixel PX may correspond to a plurality of openings OPE. In such condition, in the top view direction of the electronic device ED, the sum of the numbers of the transistors overlapped with the three first openings OP1 to which the first area A1 of a pixel PX corresponds may be less than the sum of the numbers of the transistors overlapped with the plurality of openings OPE to which the second area A2 of the pixel PX corresponds. In some embodiments, the sum of the areas of the semiconductors (such as the semiconductor SM) of the transistors overlapped with the three first openings OP1 to which the first area A1 of a pixel PX corresponds may be less than the sum of the areas of the semiconductors (such as the semiconductor SM) of the transistors overlapped with the plurality of openings OPE to which the second area A2 of the pixel PX corresponds. The feature described in the present embodiment may be applied to other embodiments and variant embodiments of the present disclosure.

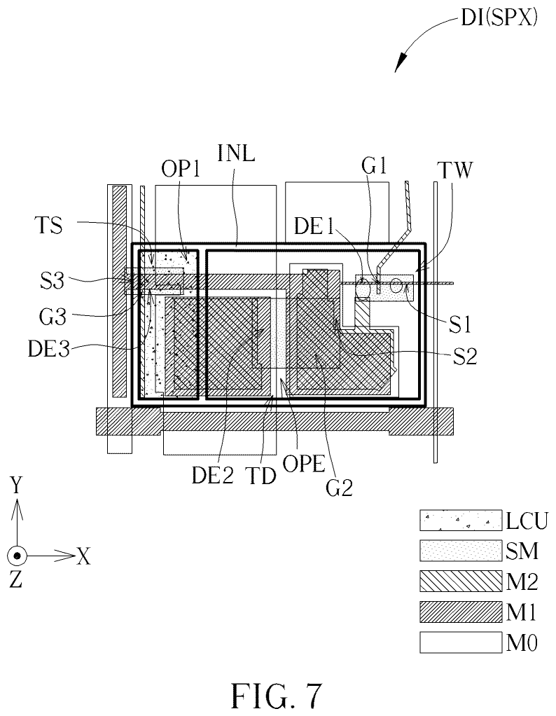

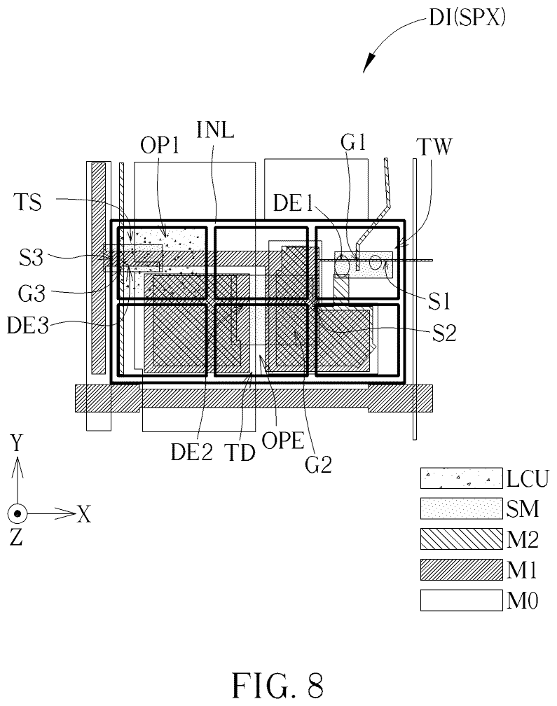

Referring to FIG. 7 and FIG. 8, FIG. 7 schematically illustrates a partial top view of an electronic device according to a sixth embodiment of the present disclosure, and FIG. 8 schematically illustrates a partial top view of an electronic device according to a variant embodiment of the sixth embodiment of the present disclosure. Specifically, FIG. 7 and FIG. 8 respectively show a top view of the driving circuit D1 of a sub-pixel SPX. The structures of the driving circuits D1 shown in FIG. 7 and FIG. 8 may refer to the structure shown in FIG. 4, FIG. 5 and described in the content above, and will not be redundantly described. According to the present embodiment, in the driving circuit D1 of a sub-pixel SPX, the number of the transistors overlapped with the first opening OP1 in which the optical unit LCU is disposed may be less than the number of the transistors overlapped with the opening OPE in which the optical unit LCU is not disposed. Specifically, in the top view of the electronic device ED, the plurality of transistors in the driving circuit D1 of a sub-pixel SPX may include a first portion of transistors overlapped with the first opening OP1 and a second portion of transistors overlapped with the opening OPE, wherein the number of the first portion of transistors may be different from the number of the second portion of transistors. In an embodiment, the number of the first portion of transistors may be less than the number of the second portion of transistors. In some embodiments, as shown in FIG. 7, in the driving circuit D1 of a sub-pixel SPX, the number of the transistors overlapped with a first opening OP1 and the number of the transistors overlapped with an opening OPE may be different, and in such condition, the plurality of transistors in the driving circuit D1 of the sub-pixel SPX may include a first portion of transistors overlapped with the first opening OP1 and a second portion of transistors overlapped with the opening OPE, wherein the number of the first portion of transistors is less than the number of the second portion of transistors. For example, in FIG. 7, the first portion of transistors may include one transistor (that is, the sensing transistor TS) overlapped with the first opening OP1, and the second portion of transistors may include two transistors (that is, the driving transistor TD and the switch transistor TW) overlapped with the opening OPE, but not limited thereto. The opening OPE described herein may be the second opening OP2 mentioned above. In other words, in the present embodiment, the first opening OP1 may overlap a first portion of a plurality of transistors, and the second opening OP2 may overlap the second portion of the plurality of transistors, and the first portion of the plurality of transistors may be different from the second portion of the plurality of transistors in quantity. For example, the number of the first portion of the plurality of transistors may be less than the number of the second portion of the plurality of transistors. In some embodiments, as shown in FIG. 8, a plurality of transistors in the driving circuit D1 of a sub-pixel SPX may overlap one first opening OP1 and a plurality of openings OPE, and in such condition, the plurality of transistors in the driving circuit D1 of the sub-pixel SPX may include the first portion of the plurality of transistors overlapped with the first opening OP1 and the second portion of the plurality of transistors overlapped with the plurality of openings OPE, wherein the number of the first portion of the plurality of transistors may be less than the number of the second portion of the plurality of transistors. “The transistors include the second portion of the plurality of transistors overlapped with the plurality of openings OPE” described herein may represent that the second portion of the plurality of transistors overlap a region to which the plurality of openings OPE correspond. For example, in FIG. 8, the first portion of the plurality of transistors may include one transistor (that is, the sensing transistor TS) overlapped with the first opening OP1, and the second portion of the plurality of transistors may include two transistor (that is, the driving transistor TD and the switch transistor TW) overlapped with the plurality of openings OPE (for example, five openings OPE in FIG. 8, but not limited thereto), but not limited thereto. It should be noted that the number of the transistors in the driving circuit D1 of a sub-pixel SPX may be determined according to the design of the driving circuit D1, which is not limited to the contents above. In some embodiments, the driving circuit D1 of a sub-pixel SPX may include X1 transistors, and the X1 transistors may include Y1 transistors (that is, the first portion of the plurality of transistors) overlapped with the first opening OP1 and Z1 transistors (that is, the second portion of the plurality of transistors) overlapped with at least one opening OPE, wherein X1 is the sum of Y1 and Z1, and Y1 may be less than Z1. The feature described in the present embodiment may be applied to other embodiments and variant embodiments of the present disclosure.

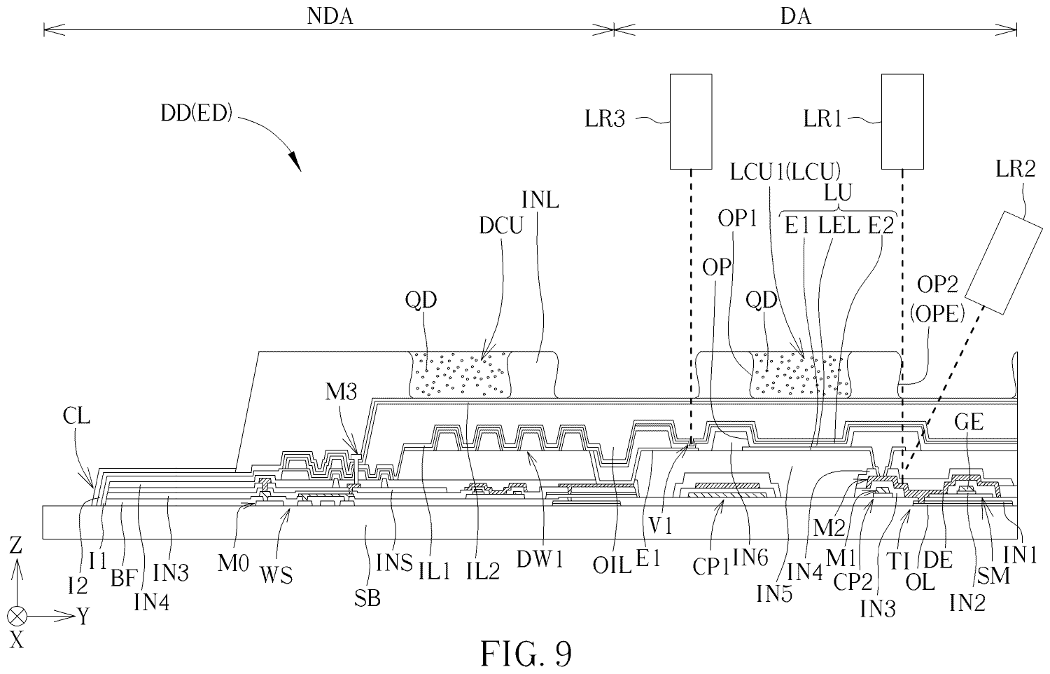

Referring to FIG. 9, FIG. 9 schematically illustrates a partial cross-sectional view of an electronic device according to a seventh embodiment of the present disclosure. Specifically, FIG. 9 shows a portion of the electronic device ED shown in FIG. 1 including the insulating layer INL and the layers and elements there below. In detail, the structure shown in FIG. 9 may for example be the structure formed after the insulating layer INL and the optical unit LCU are disposed during the manufacturing process of the electronic device ED. According to the present embodiment, since the insulating layer INL includes the opening OPE in addition to the first opening OP1 in which the optical unit LCU is disposed, after the insulating layer INL and the optical unit LCU are disposed, a specific process may further be performed on the elements or layers below the insulating layer INL through the opening OPE.

In some embodiments, since the opening OPE may overlap at least a portion of the transistor in the circuit layer CL in the top view of the electronic device ED, the position of the specific transistor may be marked through the opening OPE after the insulating layer INL and the optical unit LCU are disposed. For example, when a defective transistor is found during the inspection step of the transistors, the position of the defective transistor may be marked to facilitate the subsequent repairing process of the defective transistor. In the present embodiment, the position of the transistor may for example be marked by laser dot positioning, but not limited thereto. Specifically, as shown in FIG. 9, if it is detected that the transistor T1 is a defective transistor during the inspection step of the transistors, a laser may be emitted by a laser transmitter LR1, wherein the laser may pass through the opening OP2 (or the opening OPE) overlapping the transistor T1 and leave a mark at any suitable position corresponding to the transistor T1 (for example, the surface of the insulating layer 12 corresponding to the transistor T1, but not limited thereto). In other embodiments, the position of the transistor may be marked by computer coordinate positioning, ink color positioning or other suitable methods. In addition, after the marking step of the defective transistor, a repairing process may be performed on the defective transistor through the opening OPE. For example, as shown in FIG. 9, after the position of the transistor T1 is marked through the above-mentioned ways, a laser may be emitted by a laser transmitter LR2, wherein the laser may pass through the opening OP2 and be emitted to the transistor T1, thereby repairing the transistor T1.

In some embodiments, a drilling process may be performed on the layers or elements below the insulating layer INL through the opening OPE. For example, as shown in FIG. 9, a laser transmitter LR3 may emit a laser, wherein the laser may pass through the opening OPE may form thr via V1 in the light emitting layer LEL. The description of the via V1 may refer to the contents above, and will not be redundantly described. In other words, the via V1 may overlap or at least partially overlap the opening OPE of the insulating layer INL in the top view of the electronic device ED. FIG. 1 also shows the feature that the via V1 is overlapped with the opening OPE. Since the laser used to form the via V1 does not pass through the insulating layer INL (or the material of the insulating layer INL), the possibility of the material of the insulating layer INL being vaporized at high temperature by laser irradiation and causing contamination may be reduced. It should be noted that the opening OPE is not limited to be used to form the via V1 mentioned above, and the opening OPE may be used to perform drilling process of other layers. In such condition, the via structure formed through the opening OPE may overlap or at least partially overlap the opening OPE in the top view of the electronic device ED. In some embodiments, the electronic device ED may include a tiled display device, and a through glass via (TGV) may be formed through the opening OPE to electrically connect different electronic devices ED.

In current electronic devices, when the position of defective transistor should be marked, the defective transistor should be repaired or the via in the layers below the optical unit should be formed after the optical unit is disposed, the laser used in the processes mentioned above may be affected by the dam wall structure of the optical unit when it pass through the dam wall structure, for example, the laser may be blocked or absorbed by the material of the dam wall structure, thereby increasing the difficulty of the processes mentioned above. Or, the dam wall structure may affect the difficulty of observing the mark of the position of the transistor. In another aspect, since the insulating layer INL of the electronic device ED of the present disclosure may include the opening OPE in which the optical unit LCU is not disposed, the above-mentioned process may be performed through the opening OPE, thereby reducing the influence of the material of the insulating layer INL on the above-mentioned process. For example, the possibility of laser being blocked or absorbed by the material of the insulating layer INL may be reduced. Therefore, the yield of the manufacturing process of the electronic device ED may be improved. It should be noted that the opening OPE may further be used in other suitable processes, which is not limited to the processes above.

In addition, although it is not shown in FIG. 9, in the present embodiment, the semiconductor OL may be disposed in the peripheral region NDA and the active region DA, and in the top view of the electronic device ED, the number of openings of the insulating layer INL overlapping the semiconductor OL disposed in the peripheral region NDA is different from the number of openings of the insulating layer INL overlapping the semiconductor OL disposed in the active region DA. The openings of the insulating layer INL described herein may include the first opening OP1 in which the optical unit LCU is disposed and the opening OPE in which the optical unit LCU is not disposed. Specifically, the number of openings of the insulating layer INL overlapping the semiconductor OL disposed in the peripheral region NDA may be less than the number of openings of the insulating layer INL overlapping the semiconductor OL disposed in the active region DA, but not limited thereto.

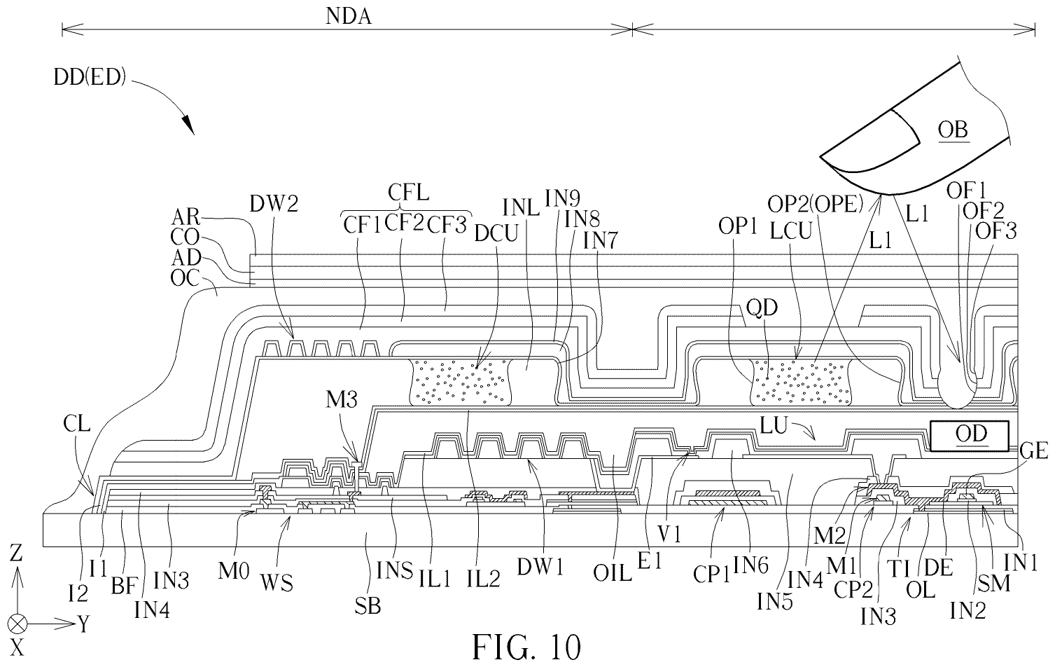

Referring to FIG. 10, FIG. 10 schematically illustrates a partial cross-sectional view of an electronic device according to an eighth embodiment of the present disclosure. According to the present embodiment, the electronic device ED may further include an optical sensor OD, wherein the optical sensor OD may be disposed between the insulating layer INL and the substrate SB. For example, as shown in FIG. 10, the optical sensor OD may be disposed on the insulating layer IN5 and located between the insulating layer IN5 and the insulating layer OIL, but not limited thereto. In other embodiments, the optical sensor OD may be disposed at any suitable position between the insulating layer INL and the substrate SB. According to the present embodiment, in the top view of the electronic device ED, at least a portion of the optical sensor OD may overlap at least one of the openings OPE of the insulating layer INL in which the optical unit LCU is not disposed. For example, as shown in FIG. 10, in the top view of the electronic device, one of the openings OPE of the insulating layer INL (such as the second opening OP2, but not limited thereto) may overlap at least a portion of the optical sensor OD. In other embodiments, the optical sensor OD may overlap a plurality of openings OPE. The optical sensor OD may include any suitable light sensing element that can receive visible or non-visible light. In the present embodiment, the optical sensor OD may for example include organic photodiode (OPD), but not limited thereto. In some embodiments, the optical sensor OD may be formed in the electronic device ED through the opening OPE of the insulating layer INL. For example, an organic photodiode may be formed in the electronic device ED through the opening OPE, but not limited thereto. In some embodiments, the optical sensor OD may be formed outside the electronic device ED at first, and then the optical sensor OD may be transferred to the electronic device ED through the opening OPE. The optical sensor OD may be electrically connected to the circuit layer CL (such as the transistors in the circuit layer CL), such that the optical sensor OD may be driven by the transistors. In the present embodiment, the optical sensor OD may for example serve as a fingerprint sensing element, but not limited thereto. For example, as shown in FIG. 10, the light L1 emitted from the light emitting unit LU may be reflected by an object OB (such as the user's finger) and be received by the optical sensor OD after passing through the opening OP2, thereby achieving the function of fingerprint recognition. In other embodiments, the optical sensor OD may include other suitable sensing element according to the design of the electronic device ED.

According to the present embodiment, a portion of the first light filtering layer CF1, a portion of the second light filtering layer CF2 and a portion of the third light filtering layer CF3 disposed in the opening OPE overlapped with at least a portion of the optical sensor OD may respectively include a light filtering opening. Specifically, as shown in FIG. 10, the second opening OP2 of the insulating layer INL may overlap at least a portion of the optical sensor OD in the top view of the electronic device ED, the portion of the first light filtering layer CF1 disposed in the second opening OP2 may include a first light filtering opening OF1, the portion of the second light filtering layer CF2 disposed in the second opening OP2 may include a second light filtering opening OF2, and the portion of the third light filtering layer CF3 disposed in the second opening OP2 may include a third light filtering opening OF3. The first light filtering opening OF1, the second light filtering opening OF2 and the third light filtering opening OF3 may at least partially overlap each other in the top view of the electronic device ED. In addition, the first light filtering opening OF1, the second light filtering opening OF2 and the third light filtering opening OF3 may overlap at least a portion of the optical sensor OD in the top view of the electronic device ED. In short, taking the structure shown in FIG. 10 as an example, the electronic device ED may include the first light filtering layer CF1 and the second light filtering layer CF2 disposed on the insulating layer INL, a portion of the first light filtering layer CF1 is disposed in the second opening OP2 and has the first light filtering opening OF1, a portion of the second light filtering layer CF2 is disposed in the second opening OP2 and has the second light filtering opening OF2, and in the top view of the electronic device ED, the first light filtering layer CF1 may overlap the optical unit LCU1, and the second light filtering layer CF2 may not overlap the optical unit LCU1. The optical layer OC may be filled into the first light filtering opening OF1, the second light filtering opening OF2 and the third light filtering opening OF3, but not limited thereto. By forming light filter openings in the above-mentioned light filtering layers, the influence of these light filtering layers on the function of the optical sensor OD may be reduced. Specifically, by forming the first light filtering opening OF1, the second light filtering opening OF2 and the third light filtering opening OF3 overlapped with at least a portion of the optical sensor OD respectively in the first light filtering layer CF1, the second light filtering layer CF2 and the third light filtering layer CF3, the light (such as the light L1) may enter the optical sensor OD through the first light filtering opening OF1, the second light filtering opening OF2 and the third light filtering opening OF3, such that the light may not be blocked or absorbed by the first light filtering layer CF1, the second light filtering layer CF2 and the third light filtering layer CF3. Therefore, the possibility that the optical sensor OD cannot receive the light signal and affect its function may be reduced. In some embodiments, as shown in FIG. 10, the insulating layer IN7, the insulating layer IN8 and the insulating layer IN9 may respectively include an opening corresponding to the first light filtering opening OF1, the second light filtering opening OF2 and the third light filtering opening OF3, and the optical layer OC may be filled into the plurality of openings.

It should be noted that the electronic device ED may further include other types of sensors overlapped with the opening OPE, which is not limited to the optical sensor OD mentioned above. For example, the electronic device ED may include a piezoelectric sensor, a haptic device, a voice sensing element, a charge-coupled device (CCD), an antenna element and other suitable elements, wherein at least a portion of these elements or devices may overlap at least one of the openings OPE.

In some embodiments, an opening OPE of the insulating layer INL may overlap a plurality of elements at the same time. For example, an opening OPE of the insulating layer INL may overlap the transistor and the optical sensor OD at the same time. For example, as shown in FIG. 10, the second opening OP2 of the insulating layer INL may overlap the optical sensor OD and the transistor T1 at the same time in the top view of the electronic device ED. In some embodiments, one of the openings OPE of the insulating layer INL may overlap one of the transistor and the optical sensor OD, and another one of the openings OPE of the insulating layer INL may overlap another one of the transistor and the optical sensor OD. For example, return to FIG. 2, in the top view of the electronic device ED, one of the openings OPE (such as the second opening OP2) of the insulating layer INL may overlap the transistor T1, and another one of the openings OPE (such as the third opening OP3) of the insulating layer INL may overlap at least a portion of the optical sensor OD.

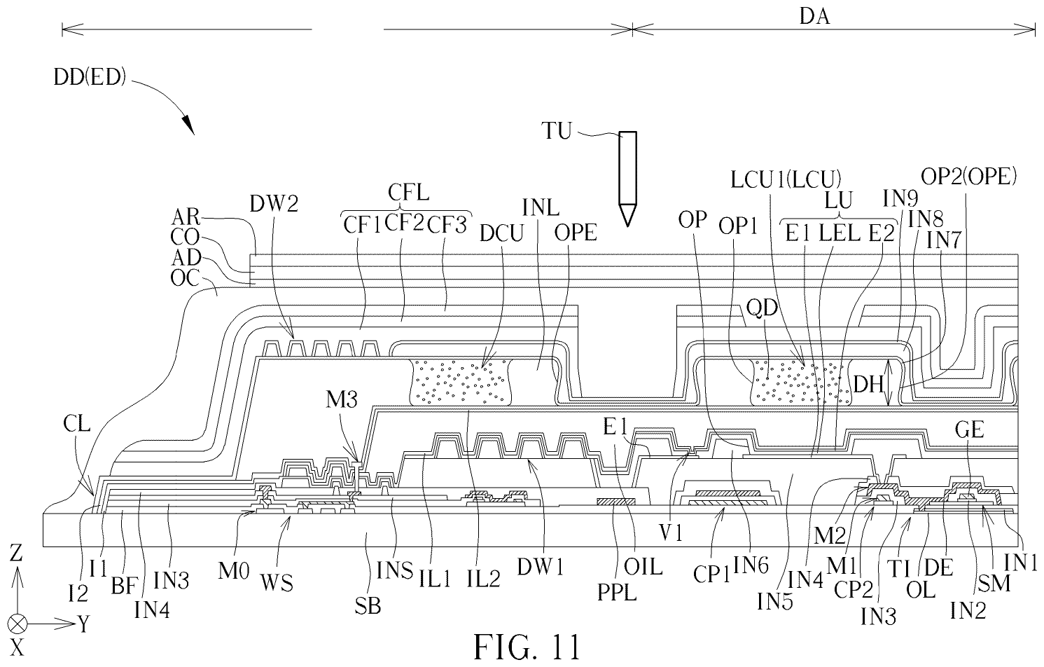

Referring to FIG. 11, FIG. 11 schematically illustrates a partial cross-sectional view of an electronic device according to a ninth embodiment of the present disclosure. According to the present embodiment, the electronic device ED may further include a pattern layer PPL disposed on the substrate SB. The pattern layer PPL may for example be disposed in the circuit layer CL, but not limited thereto. The pattern layer PPL may be formed of the conductive layers in the circuit layer CL, but not limited thereto. For example, as shown in FIG. 11, the pattern layer PPL may be formed of the conductive layer M1 and/or the conductive layer M2. The pattern layer PPL may be formed of a conductive layer and a plurality of conductive layers. In such condition, the material of the pattern layer PPL may be the same as the material of the conductive layer M1 and/or the conductive layer M2, or the pattern layer PPL and the conductive layer M1 and/or the conductive layer M2 may be formed in the same process to reduce production cost. In the top view of the electronic device ED, at least a portion of the pattern layer PPL may overlap at least one of the openings OPE of the insulating layer INL. In other words, the pattern layer PPL may be disposed corresponding to the opening OPE. In some embodiments, the pattern layer PPL may serve as alignment element. Specifically, in the manufacturing process of the electronic device ED, the pattern layer PPL may be used to assist in positioning the positions of the layers or elements, thereby reducing misalignment of the layers or elements. For example, when a small-area mask is used in the manufacturing process of the electronic device ED, the pattern layer PPL may be used to assist in positioning the small-area mask to reduce misalignment of the small-area mask, but not limited thereto. In some embodiments, the pattern layer PPL may include a code pattern, wherein the user may obtain specific information through the code pattern, wherein the specific information for example include the position information on the electronic device ED, but not limited thereto. For example, as shown in FIG. 11, the user may use the stylus TU to read the code pattern (that is, the pattern layer PPL) through the opening OPE, thereby knowing the position information on the electronic device ED corresponding to the stylus TU, but not limited to thereto. In detail, the stylus TU may emit an optical signal, wherein the optical signal may reach the pattern layer PPL through the opening OPE, thereby obtaining the pattern information of the pattern layer PPL (or the code pattern). “The optical signal of the stylus TU” described herein may include visible light signal and non-visible light signal (such as infrared light signal, but not limited thereto). The electronic device ED may for example include a plurality of pattern layers PPL disposed at different positions of the electronic device ED, wherein the plurality of pattern layers PPL may respectively serve as a code pattern to provide the information of the position where the code pattern is located, and the plurality of pattern layers PPL may respectively overlap at least one of the openings OPE of the insulating layer INL. In some embodiments, the pattern layer PPL may serve as the alignment element and the code pattern at the same time. For example, the pattern layer PPL may be used as the alignment element during the manufacturing process of the electronic device ED, and may be used as the code pattern when the electronic device ED is used. According to the present embodiment, since the pattern layer PPL may overlap the opening OPE, the influence of the insulating layer INL on the function of the pattern layer PPL may be reduced. Specifically, when the pattern layer PPL serves as the alignment element, the possibility that the position of the pattern layer PPL cannot be obtained may be reduced by making the pattern layer PPL overlap the opening OPE. Or, when the pattern layer PPL serves as the code pattern, the situation in which the optical signal emitted by the stylus TU is absorbed by the material of the insulating layer INL and resulting in the inability to read the code pattern may be reduced by making the pattern layer PPL overlap the opening OPE.

According to the present embodiment, as shown in FIG. 11, a portion of the first light filtering layer CF1, a portion of the second light filtering layer CF2 and a portion of the third light filtering layer CF3 disposed in the opening OPE overlapped with at least a portion of the pattern layer PPL may be removed. In such condition, the pattern layer PPL may not overlap the first light filtering layer CF1, the second light filtering layer CF2 and the third light filtering layer CF3 in the top view of the electronic device ED. Through the above-mentioned design, the influence of the light filtering layer on the function of the pattern layer PPL may be reduced. For example, by removing a portion of the first light filtering layer CF1, a portion of the second light filtering layer CF2 and a portion of the third light filtering layer CF3 overlapped with the pattern layer PPL, the possibility that the optical signal emitted by the stylus TU is blocked or absorbed by the first light filtering layer CF1, the second light filtering layer CF2 and the third light filtering layer CF3 and resulting in failure to read the code pattern may be reduced.

It should be noted that although it is not shown in FIG. 11, the pattern layer PPL may be formed of other materials, and the pattern layer PPL is not limited to be disposed in the circuit layer CL. For example, in some embodiments, the pattern layer PPL may be disposed in one of the openings OPE of the insulating layer INL, and the pattern layer PPL may include filtering materials, fluorescent materials, quantum dot materials or other suitable materials that can allow infrared light to pass through.

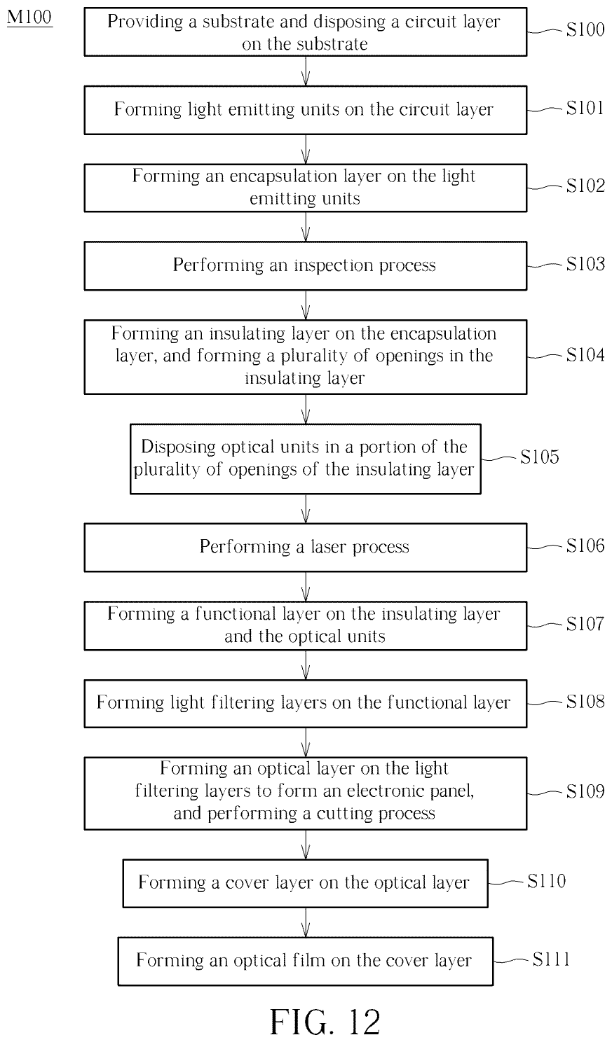

Referring to FIG. 12 as well as FIG. 1, FIG. 12 shows the flow chart of the manufacturing process of the electronic device according to the first embodiment of the present disclosure. According to the present embodiment, the manufacturing method M100 of the electronic device ED may include the following steps:
S100: providing a substrate and disposing a circuit layer on the substrate;
S101: forming light emitting units on the circuit layer;
S102: forming an encapsulation layer on the light emitting units;
S103: performing an inspection process;
S104: forming an insulating layer on the encapsulation layer, and forming a plurality of openings in the insulating layer;
S105: disposing optical units in a portion of the plurality of openings of the insulating layer;
S106: performing a laser process;
S107: forming a functional layer on the insulating layer and the optical units;
S108: forming light filtering layers on the functional layer;
S109: forming an optical layer on the light filtering layers to form an electronic panel, and performing a cutting process;
S110: forming a cover layer on the optical layer; and
S111: forming an optical film on the cover layer.

The detail of the steps in the manufacturing method M100 of the electronic device ED will be detailed in the following.

According to the present embodiment, the manufacturing method M100 of the electronic device ED may include the step S100: providing the substrate SB and disposing the circuit layer CL on the substrate SB at first. Specifically, after the substrate SB is provided, a structure formed by stacking the conductive layers and insulating layers may be formed on the substrate SB to form the elements in the circuit layer CL, such as transistors. The detail of the structures of the substrate SB and the circuit layer CL may refer to FIG. 1 and related contents above, and will not be redundantly described.

After that, the manufacturing method M100 may include the step S101: forming the light emitting units LU on the circuit layer CL. For example, as shown in FIG. 1, an encapsulation layer (that is, the insulating layer IN5) may be formed on the circuit layer CL at first, and then the electrode E1, the light emitting layer LEL and the electrode E2 are sequentially disposed on the encapsulation layer to form the light emitting unit LU, but not limited thereto. It should be noted that after the electrode E1 is disposed, the insulating layer IN6 may be disposed on the electrode E1 at first, and then the light emitting layer LEL is disposed, but not limited thereto.

After that, the manufacturing method M100 may include the step S102: forming an encapsulation layer on the light emitting units LU. According to the present embodiment, the encapsulation layer may include the structure formed by stacking the insulating layer IL1, the insulating layer OIL and the insulating layer IL2 shown in FIG. 1. For example, the encapsulation layer may be formed by sequentially disposing the insulating layer IL1, the insulating layer OIL and the insulating layer IL2 on the electrode E2.

After that, the manufacturing method M100 may include the step S103: performing an inspection process. Specifically, after the encapsulation layer is disposed, an inspection process may be performed on specific elements (such as light emitting units LU, transistors, and the like) in the formed structure.

After that, the manufacturing method M100 may include the step S104: forming the insulating layer INL on the encapsulation layer, and forming a plurality of openings in the insulating layer INL. Specifically, as shown in FIG. 1, the insulating layer INL may be formed on the encapsulation layer, and a plurality of openings (including the first opening OP1 and the openings OPE) are formed in the insulating layer INL.

After that, the manufacturing method M100 may include the step S105: disposing optical units LCU in a portion of the plurality of openings of the insulating layer INL. Specifically, as shown in FIG. 1, after the plurality of openings of the insulating layer INL are formed, each of the optical units LCU (including the optical unit LCU1, the optical unit LCU2 and the optical unit LCU3 mentioned above) may be disposed in one opening, wherein the openings in which the optical unit is disposed may be the first opening OP1 mentioned above, and the openings in which the optical unit is not disposed may be the opening OPE mentioned above.

After that, the manufacturing method M100 may include the step S106: performing a laser process. Specifically, after the optical units LCU are disposed, a laser process may be performed on the layers or elements below the insulating layer INL through the opening OPE. In some embodiments, the laser process includes repairing the defective transistor by a laser through the opening OPE. In some embodiments, the laser process includes performing a drilling process on specific layer (such as the light emitting layer LEL, but not limited thereto) by a laser through the opening OPE.

After that, the manufacturing method M100 may include the step S107: forming a functional layer on the insulating layer and the optical units. The functional layer described herein may be the insulating layer IN8 shown in FIG. 1. As mentioned above, the insulating layer IN8 may include a material with a lower refractive index than other organic layers in the electronic device ED, but not limited thereto. In some embodiments, the insulating layer IN8 may further include hollow particles filled in the organic material layer.

After that, the manufacturing method M100 may include the step S108: forming light filtering layers on the functional layer. Specifically, after the insulating layer IN7, the insulating layer IN8 and the insulating layer IN9 are disposed in sequence, the first light filtering layer CF1, the second light filtering layer CF2 and the third light filtering layer CF3 may be disposed on the insulating layer IN9 to form the light filtering layer structure CFL. It should be noted that the first light filtering layer CF1, the second light filtering layer CF2 and the third light filtering layer CF3 may be patterned, such that the portion of the light filtering layer structure CFL corresponding to an optical unit LCU may only include the light filtering layer having the same color as the light passing through the optical unit LCU.

After that, the manufacturing method M100 may include the step S109: forming the optical layer OC on the light filtering layers and performing a cutting process. Specifically, after the light filtering layer structure CFL is formed, the optical layer OC may be disposed on the light filtering layer structure CFL. After that, a cutting process may be performed on the formed structure to divide the formed structure into a plurality of electronic panels.

After that, the manufacturing method M100 may include the step S110: forming the cover layer CO on the optical layer OC and the step S111: forming an optical film on the cover layer CO. Specifically, after the optical layer OC is disposed, and the plurality of electronic panels are formed through cutting, an adhesive layer AD may be disposed on the optical layer OC of one of the electronic panels, and the cover layer CO may be disposed on the adhesive layer AD, such that the cover layer CO may be attached to the electronic panel. After that, an optical film (such as the anti-reflection layer AR shown in FIG. 1) may be disposed on the cover layer CO to form the electronic device ED, thereby improving the light emitting effect of the electronic device ED.

It should be noted that the manufacturing method M100 of the electronic device ED may further include other suitable steps, which is not limited to the steps above.

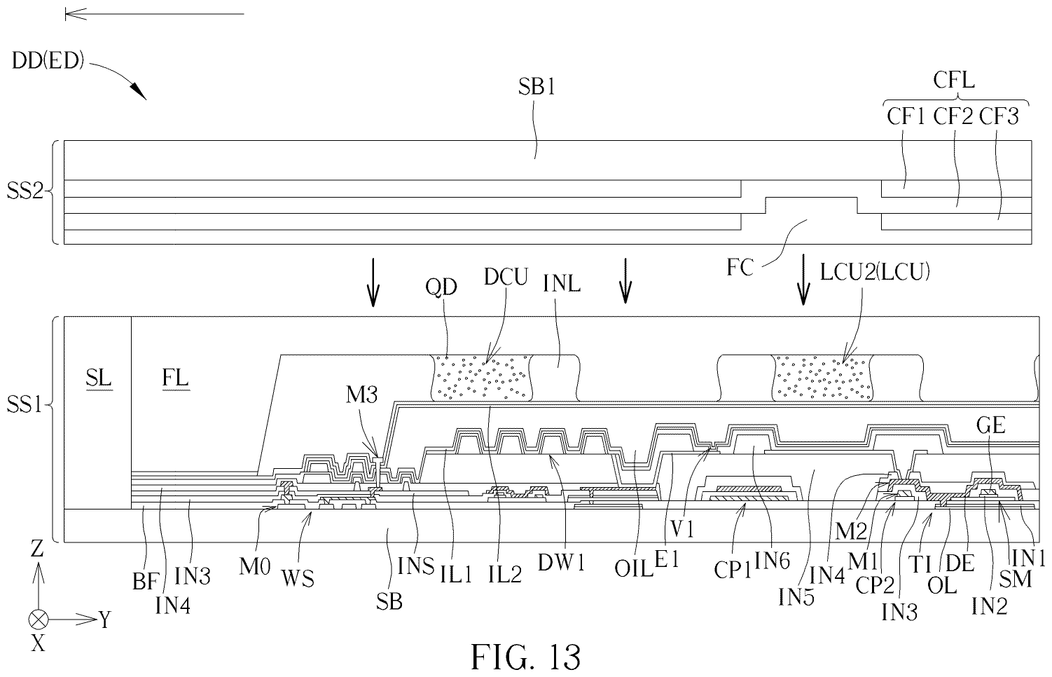

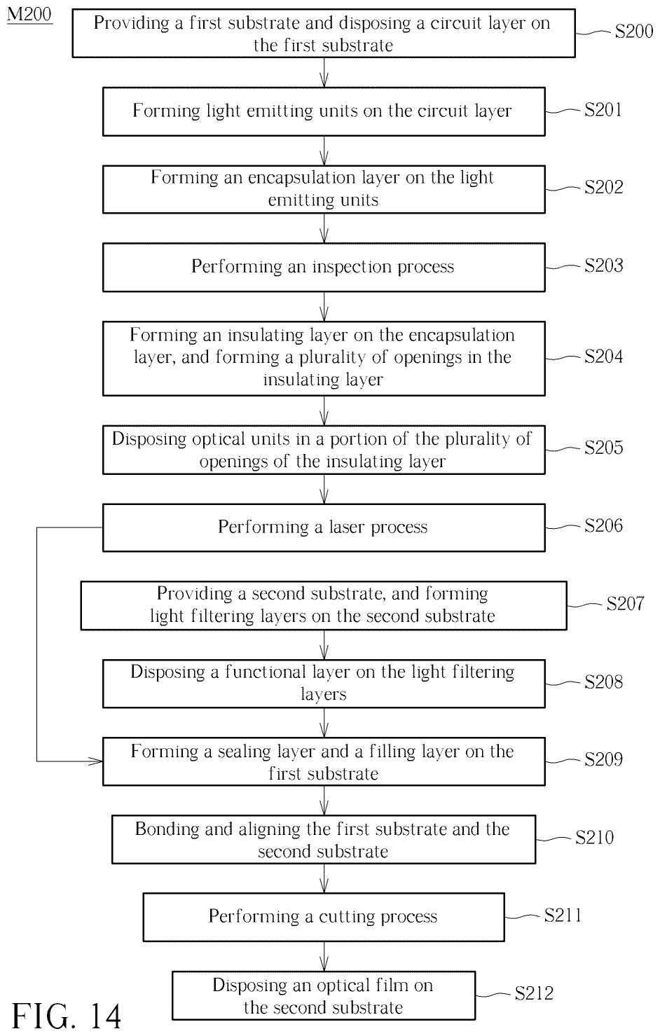

Referring to FIG. 13 and FIG. 14, FIG. 13 schematically illustrates a partial cross-sectional view of an electronic device according to a tenth embodiment of the present disclosure, and FIG. 14 shows the flow chart of the manufacturing process of the electronic device according to the tenth embodiment of the present disclosure. According to the present embodiment, the manufacturing method M200 of the electronic device ED may include the following steps:
S200: providing a first substrate and disposing a circuit layer on the first substrate;
S201: forming light emitting units on the circuit layer;
S202: forming an encapsulation layer on the light emitting units;
S203: performing an inspection process;
S204: forming an insulating layer on the encapsulation layer, and forming a plurality of openings in the insulating layer;
S205: disposing optical units in a portion of the plurality of openings of the insulating layer;
S206: performing a laser process;
S207: providing a second substrate, and forming light filtering layers on the second substrate;
S208: disposing a functional layer on the light filtering layers;
S209: forming a sealing layer and a filling layer on the first substrate;
S210: bonding and aligning the first substrate and the second substrate;
S211: performing a cutting process; and
S212: disposing an optical film on the second substrate.

The detail of the steps of the manufacturing method M200 of the electronic device ED will be detailed in the following.

According to the present embodiment, the manufacturing method M200 of the electronic device ED may include a two-substrate process. Specifically, the step S200 to the step S206 in the manufacturing method M200 may be the manufacturing process of the first substrate structure SS1 shown in FIG. 13, and the step S207 to the step S208 in the manufacturing method M200 may be the manufacturing process of the second substrate structure SS2 shown in FIG. 13. After the first substrate structure SS1 and the second substrate structure SS2 are formed, the first substrate structure SS1 and the second substrate structure SS2 may be bonded to form the electronic device ED.

The manufacturing process of the first substrate structure SS1 may include the step S200: providing the first substrate SB and disposing the circuit layer CL on the first substrate SB at first. Specifically, as shown in FIG. 13, the first substrate SB may be the substrate SB shown in FIG. 1, and the circuit layer CL may be disposed on the first substrate SB. The detail of the structures of the first substrate SB and the circuit layer CL may refer to the contents above, and will not be redundantly described.

After that, the manufacturing process of the first substrate structure SS1 may include the step S201 to the step S206, wherein the detail of the step S201 to the step S206 may respectively refer to the contents of the step S101 to the step S106 mentioned above, and will not be redundantly described. After the step S206 is completed, the first substrate structure SS1 may be formed. The structural feature of the first substrate structure SS1 may refer to the structure of a portion of the electronic device ED shown in FIG. 1, and will not be redundantly described.

The manufacturing process of the second substrate structure SS2 may include the step S207: providing the second substrate SB1, and forming light filtering layers on the second substrate SB1 at first. Specifically, as shown in FIG. 13, the second substrate SB1 may be provided at first, and then the first light filtering layer CF1, the second light filtering layer CF2 and the third light filtering layer CF3 may be disposed on the second substrate SB1 to form the light filtering layer structure CFL. It should be noted that the first light filtering layer CF1, the second light filtering layer CF2 and the third light filtering layer CF3 may be patterned, such that the portion of the light filtering layer structure CFL corresponding to an optical unit LCU may only include the light filtering layer having the same color as the light passing through the optical unit LCU after the second substrate structure SS2 and the first substrate structure SS1 are bonded in subsequent process. FIG. 13 for example shows the structure in which a portion of the first light filtering layer CF1 and a portion of the third light filtering layer CF3 corresponding to the optical unit LCU are removed, and the second light filtering layer CF2 corresponds to the optical unit LCU. In such condition, the optical unit LCU shown in FIG. 13 may be the optical unit LCU2.

After that, the manufacturing process of the second substrate structure SS2 may include the step S208: disposing the functional layer FC on the light filtering layers. Specifically, after the light filtering layer structure CFL is disposed on the second substrate SB1, the functional layer FC may be disposed on the light filtering layer structure CFL. The functional layer FC of the present embodiment may for example refer to the insulating layer IN8 shown in FIG. 1, but not limited thereto. After the functional layer FC is disposed, the second substrate structure SS2 may be formed.

It should be noted that the manufacturing processes of the first substrate structure SS1 and the second substrate structure SS2 mentioned above may be performed in any order or performed at the same time, it is not limited in the present embodiment. In addition, the first substrate structure SS1 and the second substrate structure SS2 may further include other suitable elements or layers, which are not limited to the structures shown in FIG. 13.

After the first substrate structure SS1 and the second substrate structure SS2 are formed, the manufacturing method M200 of the electronic device ED may include the step S209: forming the sealing layer SL and the filling layer FL on the first substrate. Specifically, as shown in FIG. 13, after the first substrate structure SS1 is formed, the sealing layer SL may be disposed on the first substrate structure SS1 at first. The sealing layer SL may for example be disposed to surround the first substrate structure SS1 and may have a ring structure, but not limited thereto. After the sealing layer SL is disposed, the filling layer FL may be disposed corresponding to the region enclosed by the sealing layer SL on the first substrate structure SS1 and cover the elements and/or layers of the first substrate structure SS1. The filling layer FL may include any suitable transparent material. In another embodiment, the sealing layer SL may be disposed on the second substrate structure SS2 at first, and then the filling layer FL may be disposed corresponding to the region enclosed by the sealing layer SL on the second substrate structure SS2.

After that, the manufacturing method M200 of the electronic device ED may include the step S210: bonding and aligning the first substrate and the second substrate. Specifically, as shown in FIG. 13, after the sealing layer SL and the filling layer FL are disposed, the second substrate structure SS2 may be flipped and be bonded to and aligned with the first substrate structure SS1, such that the first substrate SB and the second substrate SB1 may respectively be located at two sides of the electronic device ED, and the elements and/or layers in the electronic device ED may be located between the first substrate SB and the second substrate SB1.

After that, the manufacturing method M200 of the electronic device ED may include the step S211: performing a cutting process. Specifically, after the first substrate structure SS1 is bonded to and aligned with the second substrate structure SS2, a cutting process may be performed to the formed structure to divide it into a plurality of electronic panels.

After that, the manufacturing method M200 of the electronic device ED may include the step S212: disposing an optical film on a side of the second substrate SB1 opposite to the light filtering layer structure CFL. Specifically, although it is not shown in the figure, after the electronic panel is formed through the cutting process, an optical film (such as the anti-reflection layer AR shown in FIG. 1) may be formed on the second substrate SB1 of an electronic panel to form the electronic device ED, thereby improving the light emitting effect of the electronic device ED.

It should be noted that the manufacturing method M200 of the electronic device ED may further include other suitable steps, which is not limited to the steps above.

In summary, an electronic device is provided by the present disclosure. The electronic device includes an insulating layer disposed on the light emitting unit, wherein the insulating layer includes a plurality of openings. The optical units may be disposed in a portion of the plurality of openings of the insulating layer, and the optical unit may not be disposed in another portion of the plurality of openings, wherein the another portion of the openings may be overlapped with specific element (such as transistor, optical sensor, and the like) in the electronic device in the top view of the electronic device. Through the above-mentioned design, specific process on the elements or layers below the insulating layer may be performed through the opening in which the optical unit is not disposed, thereby improving the yield of the manufacturing process of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a plurality of transistors disposed on the substrate;
a light emitting unit disposed on at least one of the plurality of transistors;
a first insulating layer disposed on the light emitting unit and having a first opening and a second opening; and
an optical unit disposed in the first opening;
wherein in a top view of the electronic device, the first opening is overlapped with at least a portion of the light emitting unit, and the second opening is overlapped with at least a portion of the at least one of the plurality of transistors.

2. The electronic device as claimed in claim 1, wherein the second opening is overlapped with a gate electrode of one of the at least one of the plurality of transistors, and the second opening is greater than the gate electrode in width.

3. The electronic device as claimed in claim 1, wherein the second opening is overlapped with a source electrode of one of the at least one of the plurality of transistors, and the second opening is greater than the source electrode in width.

4. The electronic device as claimed in claim 1, wherein the second opening is overlapped with a drain electrode of one of the at least one of the plurality of transistors, and the second opening is greater than the drain electrode in width.

5. The electronic device as claimed in claim 1, wherein one of the at least one of the plurality of transistors comprises a first semiconductor and a second semiconductor, and the second semiconductor is disposed between the first semiconductor and the substrate.

6. The electronic device as claimed in claim 5, further comprising a second insulating layer disposed between the first semiconductor and the second semiconductor, wherein the second insulating layer directly contacts the second semiconductor.

7. The electronic device as claimed in claim 6, wherein the second insulating layer comprises a metal oxide material.

8. The electronic device as claimed in claim 5, wherein the one of the at least one of the plurality of transistors comprises a source electrode and a drain electrode, and one of the source electrode and the drain electrode is electrically connected to the first semiconductor and the second semiconductor.

9. The electronic device as claimed in claim 5, wherein the second semiconductor is less than the first semiconductor in thickness.

10. The electronic device as claimed in claim 1, further comprising a third insulating layer disposed on the first insulating layer, wherein a portion of the third insulating layer is disposed in the second opening.

11. The electronic device as claimed in claim 1, further comprising a first light filtering layer disposed on the first insulating layer, wherein a portion of the first light filtering layer is disposed in the second opening, and in the top view of the electronic device, the first light filtering layer is overlapped with the optical unit.

12. The electronic device as claimed in claim 11, further comprising a second light filtering layer disposed on the first insulating layer, wherein a portion of the second light filtering layer is disposed in the second opening, and in the top view of the electronic device, the second light filtering layer is not overlapped with the optical unit.

13. The electronic device as claimed in claim 1, further comprising an optical sensor disposed between the first insulating layer and the substrate, wherein in the top view of the electronic device, the second opening is overlapped with at least a portion of the optical sensor.

14. The electronic device as claimed in claim 13, further comprising a first light filtering layer disposed on the first insulating layer, wherein a portion of the first light filtering layer is disposed in the second opening and having a first light filtering opening, and in the top view of the electronic device, the first light filtering layer is overlapped with the optical unit.

15. The electronic device as claimed in claim 14, further comprising a second light filtering layer disposed on the first insulating layer, wherein a portion of the second light filtering layer is disposed in the second opening and having a second light filtering opening, and in the top view of the electronic device, the second light filtering layer is not overlapped with the optical unit.

16. The electronic device as claimed in claim 1, further comprising an optical sensor disposed between the first insulating layer and the substrate, wherein the first insulating layer comprises a third opening, and in the top view of the electronic device, the third opening is overlapped with at least a portion of the optical sensor.

17. The electronic device as claimed in claim 1, wherein the first opening is overlapped with a first portion of the plurality of transistors, the second opening is overlapped with a second portion of the plurality of transistors, and the first portion of the plurality of transistors is different from the second portion of the plurality of transistors in quantity.

18. The electronic device as claimed in claim 17, wherein a quantity of the first portion of the plurality of transistors is less than a quantity of the second portion of the plurality of transistors.
